(19) United States
(12) Patent Application Publication
(10) Pub. No.: US 2025/0294846 A1
(43) Pub. Date: Sep. 18, 2025

(54) BACKSIDE CROSS-COUPLE INTERCONNECTS

(71) Applicant: Intel Corporation, Santa Clara, CA (US)

(72) Inventor: Hwichan Jun, Portland, OR (US)

(73) Assignee: Intel Corporation, Santa Clara, CA (US)

(21) Appl. No.: 18/602,603

(22) Filed: Mar. 12, 2024

(51) Int. Cl. H01L 29/417; H01L 23/528; H01L 27/092; H01L 29/06; H01L 29/423; H01L 29/775; H01L 29/786

(52) U.S. Cl. CPC H10D 64/254; H01L 23/5286; H10D 30/43; H10D 30/6735; H10D 30/6757; H10D 62/121; H10D 84/85

(57) ABSTRACT

Techniques are provided herein to form an integrated circuit having a backside interconnect structure coupled between different transistor elements, such as between source or drain regions and/or gate structures. The backside interconnect structure may be used to replace frontside local interconnect structures, thus freeing up more space in the frontside interconnect region. In one such example, a first semiconductor device includes a first semiconductor region extending from a first source or drain region and a first gate structure extending over the first semiconductor region, and a second semiconductor device includes a second semiconductor region extending from a second source or drain region and a second gate structure extending over the second semiconductor region. A conductive structure is coupled between a bottom surface of each of the first source or drain region, the second source or drain region, and a portion of the first gate structure.

### BACKGROUND

As integrated circuits continue to scale downward in size, a number of challenges arise. For instance, reducing the size of memory and logic cells within the interconnect structure is becoming increasingly more difficult, as is reducing device spacing at the device layer. Routing multiple logic signals between transistor elements in the interconnect region leads to inefficient use of the space and crowded metal lines that can increase parasitic effects. Accordingly, there remain a number of non-trivial challenges with respect to forming such high-density semiconductor devices.

### BRIEF DESCRIPTION OF THE DRAWINGS

FIG. 1A is a top-down view of an integrated circuit structure that includes a backside interconnect to route logic signals between different source or drain regions and a gate structure, in accordance with an embodiment of the present disclosure.

FIGS. 1B and 1C are different cross-sectional views of the integrated circuit of FIG. 1A that show the backside interconnect coupled to a source or drain region and a gate of the same transistor (1B) and coupled between adjacent source or drain regions of different transistors (1C), in accordance with an embodiment of the present disclosure.

FIGS. 2A and 2B are cross-sectional views that illustrate one stage in an example process for forming an integrated circuit configured with a backside interconnect such as shown in FIGS. 1A-C, in accordance with an embodiment of the present disclosure.

FIGS. 3A and 3B are cross-sectional views that illustrate another stage in the example process for forming an integrated circuit configured with a backside interconnect such as shown in FIGS. 1A-C, in accordance with an embodiment of the present disclosure.

FIGS. 4A and 4B are cross-sectional views that illustrate another stage in the example process for forming an integrated circuit configured with a backside interconnect such as shown in FIGS. 1A-C, in accordance with an embodiment of the present disclosure.

FIGS. 5A and 5B are cross-sectional views that illustrate another stage in the example process for forming an integrated circuit configured with a backside interconnect such as shown in FIGS. 1A-C, in accordance with an embodiment of the present disclosure.

FIGS. 6A and 6B are cross-sectional views that illustrate another stage in the example process for forming an integrated circuit configured with a backside interconnect such as shown in FIGS. 1A-C, in accordance with an embodiment of the present disclosure.

FIGS. 7A and 7B are cross-sectional views that illustrate another stage in the example process for forming an integrated circuit configured with a backside interconnect such as shown in FIGS. 1A-C, in accordance with an embodiment of the present disclosure.

FIGS. 8A and 8B are cross-sectional views that illustrate another stage in the example process for forming an integrated circuit configured with a backside interconnect such as shown in FIGS. 1A-C, in accordance with an embodiment of the present disclosure.

FIGS. 9A and 9B are cross-sectional views that illustrate another stage in the example process for forming an integrated circuit configured with a backside interconnect such as shown in FIGS. 1A-C, in accordance with an embodiment of the present disclosure.

FIGS. 10A and 10B are cross-sectional views that illustrate another stage in the example process for forming an integrated circuit configured with a backside interconnect such as shown in FIGS. 1A-C, in accordance with an embodiment of the present disclosure.

FIGS. 11A and 11B are cross-sectional views that illustrate another stage in the example process for forming an integrated circuit configured with a backside interconnect such as shown in FIGS. 1A-C, in accordance with an embodiment of the present disclosure.

FIGS. 12A and 12B are cross-sectional views that illustrate another stage in the example process for forming an integrated circuit configured with a backside interconnect such as shown in FIGS. 1A-C, in accordance with an embodiment of the present disclosure.

FIGS. 13A and 13B are cross-sectional views that illustrate another stage in the example process for forming an integrated circuit configured with a backside interconnect such as shown in FIGS. 1A-C, in accordance with an embodiment of the present disclosure.

FIGS. 14A and 14B are cross-sectional views that illustrate another stage in the example process for forming an integrated circuit configured with a backside interconnect such as shown in FIGS. 1A-C, in accordance with an embodiment of the present disclosure.

FIG. 15 is a cross-sectional view of the integrated circuit with the backside interconnect and a backside power rail, in accordance with an embodiment of the present disclosure.

FIG. 16A is a circuit schematic of an SRAM cell.

FIG. 16B is a top-down view of a transistor layout for the SRAM cell of FIG. 16A having backside interconnects to make the local cross-couple connections, according to an embodiment of the present disclosure.

FIG. 17 illustrates a cross-sectional view of a chip package containing one or more semiconductor dies, in accordance with some embodiments of the present disclosure.

FIG. 18 is a flowchart of a fabrication process for a semiconductor device having a backside interconnect such as shown in FIGS. 1A-C, in accordance with an embodiment of the present disclosure.

FIG. 19 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., some features may have tapered sidewalls and/or rounded corners), and some features may have surface topology or otherwise be non-smooth, given real world limitations of the processing equipment and techniques used.

### DETAILED DESCRIPTION

Techniques are provided herein to form an integrated circuit having a backside interconnect structure coupled between different transistor elements, such as between source or drain regions and/or gate structures. The backside interconnect structure may be used to replace frontside local interconnect structures, thus freeing up more space in the frontside interconnect region (e.g., for metal 0 lines). The techniques can be used in any number of integrated circuit applications and are particularly useful with respect to logic and memory cells, such as those cells that use finFETs or gate-all-around transistors (e.g., ribbonFETs and nanowire FETs) or forksheet transistors (e.g., nanosheet FETs). In one such example, a first semiconductor device includes a first semiconductor region extending from a first source or drain region and a first gate structure extending over the first semiconductor region, and a second semiconductor device includes a second semiconductor region extending from a second source or drain region and a second gate structure extending over the second semiconductor region. A conductive structure is coupled between a bottom surface of each of the first source or drain region, the second source or drain region, and the first gate structure. The conductive structure may be formed on the backside of the integrated circuit following the removal of the substrate from the backside. Numerous variations and embodiments will be apparent in light of this disclosure.

### General Overview

As previously noted above, there remain a number of non-trivial challenges with respect to integrated circuit fabrication. In more detail, some circuit designs require complex connections to be made between various transistor elements of a given device layer. Due to inherent constraints in transistor layout, providing these connections often requires the use of local interconnect layers within the interconnect region. The interconnect region includes one or more interconnect levels formed above the devices of the device layer during backend processing (sometimes called back end of line or BEOL processing). However, the presence of the local interconnect layers decreases the amount of space available for certain signal tracks within the lower interconnect levels, such as metal 0 lines. In a particular example, SRAM cells are commonly used in memory architectures and utilize local interconnects between various transistor elements. These local interconnects use up much of the available space above the devices, making it more difficult to route power, ground, bitline, and wordline connections to the transistors.

Thus, and in accordance with an embodiment of the present disclosure, techniques are provided herein to form backside interconnect structures to provide connection between any number of transistor source or drain regions and/or gate structures. In some examples, the backside interconnect structures are used instead of the frontside local interconnect layers, which can free up more space for metal 0 signal tracks in the interconnect region. According to some embodiments, a given backside interconnect structure may extend linearly between adjacent source or drain regions, or may have a non-linear shape to extend between the backside of any transistor elements, such as source or drain regions and gate structures. For example, the backside interconnect structure may have an ‘L’ shape to connect adjacent source or drain regions aligned along a Y-direction with one or more gate structures (or conductive portions of a gate trench) aligned with any of the source or drain regions along the X-direction. In some examples, the backside interconnect structure extends beneath any number of source or drain regions without providing any electrical connection with them (e.g., flying under the source or drain regions). The backside interconnect structure may include any suitable conductive material, such as tungsten, titanium, tantalum, ruthenium, molybdenum, or cobalt, or a nitride of any of these. In some examples, the backside interconnect structure includes a conductive liner of titanium nitride, to name one example.

According to an embodiment, an integrated circuit includes a first semiconductor device having a first semiconductor region extending in a first direction from a first source or drain region and a first gate structure extending over the first semiconductor region in a second direction different from the first direction, and a second semiconductor device having a second semiconductor region extending in the first direction from a second source or drain region and a second gate structure extending over the second semiconductor region in the second direction. The second source or drain region is spaced from the first source or drain region along the second direction. The integrated circuit also includes a conductive structure on an underside of each of the first source or drain region, the second source or drain region, and the first gate structure.

According to another embodiment, an integrated circuit includes a first semiconductor device having a first semiconductor region extending in a first direction from a first source or drain region and a first gate structure extending over the first semiconductor region in a second direction different from the first direction, a second semiconductor device having a second semiconductor region extending in the first direction from the first source or drain region and a second gate structure extending over the second semiconductor region in the second direction, a third semiconductor device having a third semiconductor region extending in the first direction from a second source or drain region and a third gate structure extending over the third semiconductor region in the second direction, a fourth semiconductor device having a fourth semiconductor region extending in the first direction from a third source or drain region and a fourth gate structure extending over the fourth semiconductor region in the second direction, a fifth semiconductor device having a fifth semiconductor region extending in the first direction from a fourth source or drain region and a fifth gate structure extending over the fifth semiconductor region in the second direction, and a sixth semiconductor device having a sixth semiconductor region extending in the first direction from the fourth source or drain region and a sixth gate structure extending over the sixth semiconductor region in the second direction. The first gate structure and the third gate structure are coupled together in a first gate trench, and the fourth gate structure and the sixth gate structure coupled together in a second gate trench parallel to the first gate trench. The integrated circuit further includes a conductive structure on an underside of each of the first source or drain region, the second source or drain region, and a conductive portion of the second gate trench.

According to another embodiment, a method of forming an integrated circuit includes: forming a first fin comprising a first semiconductor region and a second fin comprising a second semiconductor region extending above a substrate; forming a first dielectric layer adjacent to a subfin portion of each of the first and second fins; forming sacrificial gates and spacer structures over the first fin and the second fin; removing portions of the first fin and the second fin not covered by the sacrificial gates and spacer structures; forming a first source or drain region at an exposed end of the first semiconductor region and a second source or drain region at an exposed end of the second semiconductor region; replacing the sacrificial gates with a first gate structure over the first semiconductor region and a second gate structure over the second semiconductor region; removing the substate to expose a backside of the first dielectric layer; replacing the subfin portion of each of the first and second fins with a second dielectric layer; forming a recess through both the first dielectric layer and the second dielectric layer such that a bottom surface of the first source or drain region, a bottom surface of the second source or drain region, and a bottom surface of the first gate structure are exposed; and forming a conductive structure within the recess.

The techniques can be used with any type of non-planar transistors, including finFETs (sometimes called double-gate transistors, or tri-gate transistors), or nanowire and nanoribbon transistors (sometimes called gate-all-around transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process), or any other gate formation process. Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate the presence of a backside conductive layer beneath the transistors that extends between different source or drain regions and/or gate structures. The backside conductive layer may be in a first backside interconnect layer while additional backside interconnect layers may be provided beneath the first backside interconnect layer. One or more additional conductive layers may be provided within any of the additional backside interconnect layers, such as a power or ground rail.

It should be readily understood that the meaning of “above” and “over” in the present disclosure should be interpreted in the broadest manner such that “above” and “over” not only mean “directly on” something but also include the meaning of over something with an intermediate feature or a layer therebetween. Further, spatially relative terms, such as “beneath,” “below,” “lower,” “above,” “upper,” “top,” “bottom,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally different, then one of the material has an element that is not in the other material.

### Architecture

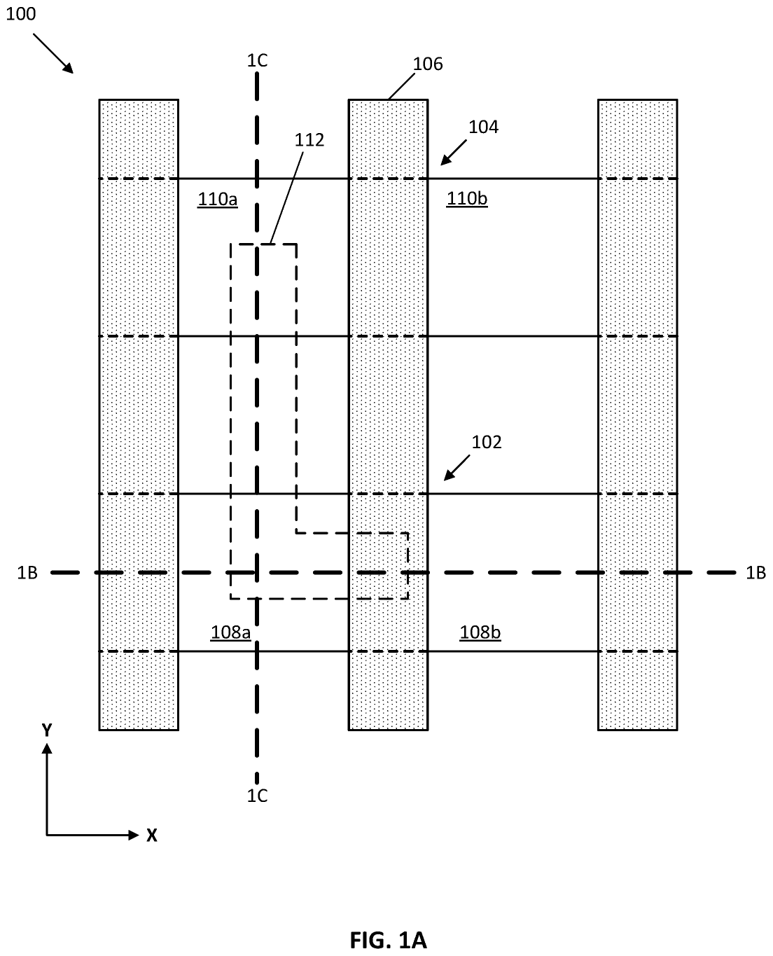

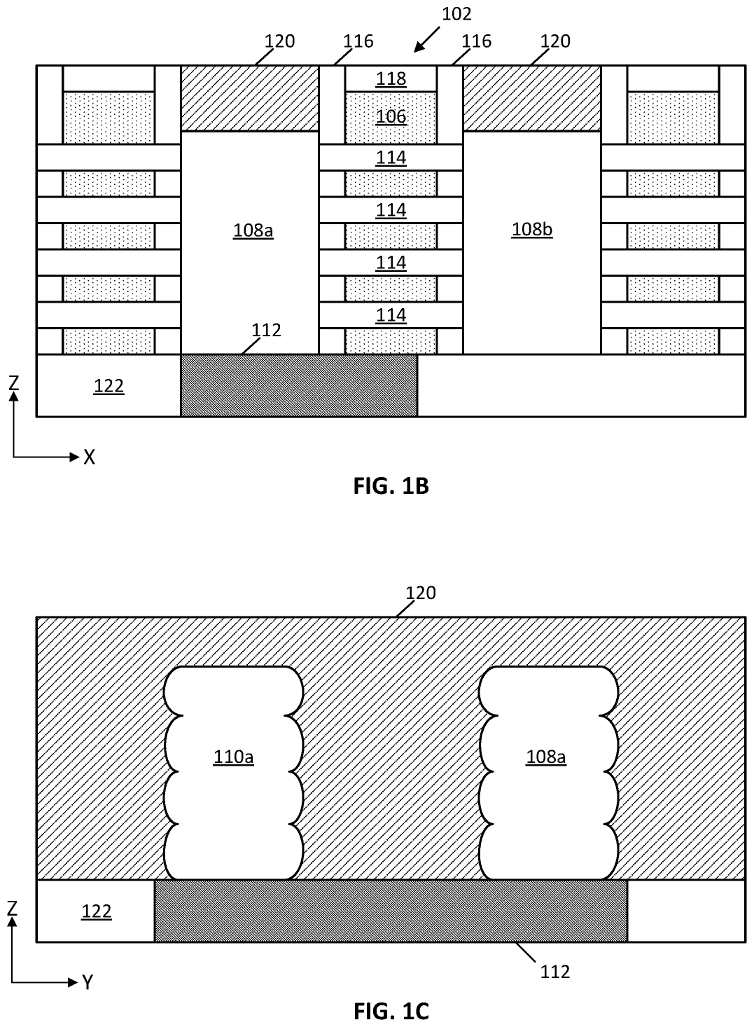

FIG. 1A is top-down view of a portion of an integrated circuit 100 that includes various semiconductor devices, such as a first semiconductor device 102 and an adjacent second semiconductor device 104, in accordance with an embodiment of the present disclosure. FIG. 1B illustrates a cross-section view across the XZ plane identified by the dashed line along the X-axis in FIG. 1A, according to an embodiment. FIG. 1C illustrates a cross-section view across the YZ plane identified by the dashed line along the Y-axis in FIG. 1A, according to an embodiment. Each of the semiconductor devices may be non-planar metal oxide semiconductor (MOS) transistors, such as tri-gate (e.g., finFET) or gate-all-around (GAA) transistors, although other transistor topologies and types could also benefit from the techniques provided herein. The examples herein illustrate semiconductor devices with a GAA structure (e.g., having nanoribbons or nanowires that extend between source and drain regions).

The semiconductor devices 102/104 include semiconductor regions that extend in a first direction (e.g., along the X-axis) between corresponding source or drain regions with a gate structure 106 extending in a second direction (e.g., along the Y-axis) across the semiconductor regions. In the illustrated example, gate structure 106 covers the semiconductor regions extending between source or drain regions, but these regions can be seen in the cross-section view of FIG. 1B. Any number of parallel gate structures 106 may be formed across the integrated circuit to form any number of transistors. According to some embodiments, first semiconductor device 102 and second semiconductor device 104 share the same gate structure 106. In some examples, a dielectric gate cut may separate gate structure 106 into separate gate structures for each of first semiconductor device 102 and second semiconductor device 104.

According to some embodiments, first semiconductor device 102 includes a semiconductor region extending along the first direction between a first source or drain region 108a and a second source or drain region 108b, and second semiconductor device 104 includes a semiconductor region extending along the first direction between a third source or drain region 110a and a fourth source or drain region 110b. Any semiconductor materials suitable for source and drain regions can be used (e.g., group IV and group III-V semiconductor materials) for any of the illustrated source or drains regions 108/110. In any such cases, the composition and doping of the source or drain regions may be the same or different, depending on the polarity of the transistors. In an example, first semiconductor device 102 is a NMOS device and first and second source or drain regions 108a/108b are doped with n-type dopants (e.g., phosphorous or arsenic), and second semiconductor device 104 is a PMOS device and third and fourth source or drain regions 110a/110b are doped with p-type dopants (e.g., boron). Any number of source and drain configurations and materials can be used. In some embodiments, second source or drain region 108b is omitted (e.g., replaced with a dielectric material).

According to some embodiments, a backside conductive layer 112 is provided beneath the devices to connect between any number of the transistor elements. In the illustrated example, backside conductive layer 112 connects at least first source or drain region 108a, third source or drain region 110a, and the portion of gate structure 106 between first source or drain region 108a and second source or drain region 108b. Backside conductive layer 112 may include any suitable conductive material, such as tungsten, titanium, tantalum, ruthenium, molybdenum, or cobalt, or a nitride of any of these. Backside conductive layer 112 may also include a conductive liner that includes titanium nitride. According to some embodiments, backside conductive layer 112 may be patterned to have a non-linear shape to connect between different elements that are not all aligned along either the X or Y axis. In the illustrated example, backside conductive layer 112 includes an ‘L’ shape with a first section extending along the first direction between first source or drain region 108a and gate structure 106 and a second section extending along the second direction between third source or drain region 110a and first source or drain region 108a.

FIGS. 1B and 1C provide more detailed cross-section views along both sections of backside conductive layer 112, according to some embodiments. Note that the same first source or drain region 108a is provided in each of the orthogonal cross-sections. FIG. 1B illustrates the first section of backside conductive layer 112 extending beneath and between first source or drain region 108a and gate structure 106. Also shown is the semiconductor region of first semiconductor device 102, which includes one or more nanoribbons 114, according to some embodiments. Nanoribbons 114 may be parts of fins that are formed of material deposited onto a substrate. The fins include alternating layers of material (e.g., alternating layers of silicon and SiGe) that facilitates forming of the nanowires or nanoribbons during a gate forming process where one type of the alternating layers is selectively etched away so as to liberate the other type of alternating layers within the channel region, so that a gate-all-around process can then be carried out. In other embodiments, a solid fin of semiconductor material (e.g., silicon or silicon germanium) is provided as the semiconductor region extending between first source or drain region 108a and second source or drain region 108b.

Gate structure 106 extends over nanoribbons 114 along second direction (e.g., along the Y-axis) to form the transistor gate (or a dummy gate structure in examples where second source or drain region 108b is omitted). Gate structure 106 may include a gate dielectric and a gate electrode on the gate dielectric. The gate electrode may represent any number of conductive layers and the gate dielectric may represent any number of dielectric layers. The gate electrode may include any sufficiently conductive material such as a metal, metal alloy, or doped polysilicon. In some embodiments, the gate electrode includes one or more workfunction metals around nanoribbons 114. In some embodiments, p-channel devices include a workfunction metal having titanium around its one or more semiconductor regions and n-channel devices include a workfunction metal having tungsten around its one or more semiconductor regions. The gate electrode may also include a fill metal or other conductive material around the workfunction metals to provide the whole gate electrode structure. The gate dielectric may include any suitable gate dielectric material(s). In some embodiments, the gate dielectric includes a layer of native oxide material (e.g., silicon oxide) on nanoribbons 114 or other semiconductor regions, and a layer of high-k dielectric material (e.g., hafnium oxide) on the native oxide.

According to some embodiments, spacer structures 116 are present along the sidewalls of gate structure 106. Spacer structures 116 may be any suitable dielectric material, such as silicon nitride, and provide separation between gate structure 106 and the adjacent source or drain regions 108a/108b. Spacer structures 116 may run along the gate structure sidewalls in the second direction and extend the entire height of gate structure 106 along the Z-axis. In some embodiments, a gate cap 118 is provided over gate structure 106 and may run along gate structure 106 in the second direction. Gate cap 118 may be any suitable dielectric material, such as silicon nitride. In some examples, gate cap 118 is the same dielectric material as spacer structures 116.

FIG. 1C illustrates the second section of backside conductive layer 112 extending beneath and between first source or drain region 108a and third source or drain region 110a. The source/drain trench illustrated in FIG. 1C may include a dielectric fill 120 around and/or over the various source or drain regions aligned within the source/drain trench. Dielectric fill 120 may also be seen over the top of first source or drain region 108a and second source or drain region 108b in FIG. 1B. Dielectric fill 120 may include any suitable dielectric material, such as silicon dioxide.

According to some embodiments, a backside dielectric layer 122 is provided beneath the semiconductor devices. Backside dielectric layer 122 may represent a single dielectric layer or multiple dielectric layers or materials. Backside dielectric layer 122 may be a first layer of a backside interconnect structure, according to some embodiments. Backside conductive layer 112 may extend through backside dielectric layer 122 to contact the bottom surface of any number of transistor elements. In the illustrated example, backside conductive layer 112 contacts the bottom surfaces of first source or drain region 108a, third source or drain region 110a, and gate structure 106. Note that any gate dielectric is removed from the bottom surface of gate structure 106 such that backside conductive layer 112 directly contacts the gate electrode of gate structure 106. Backside dielectric layer 122 may be any suitable dielectric material, such as silicon dioxide.

According to some embodiments, any number of frontside conductive contacts can be formed on the top surface of one or more source or drain regions. In an example, portions of dielectric fill 120 are removed from over any number of source or drain regions and the frontside contacts are formed in their place on the top surfaces of the source or drain regions. The frontside conductive contacts may include any suitable conductive material, such as tungsten, titanium, tantalum, ruthenium, molybdenum, or cobalt, or a nitride of any of these.

### Fabrication Methodology

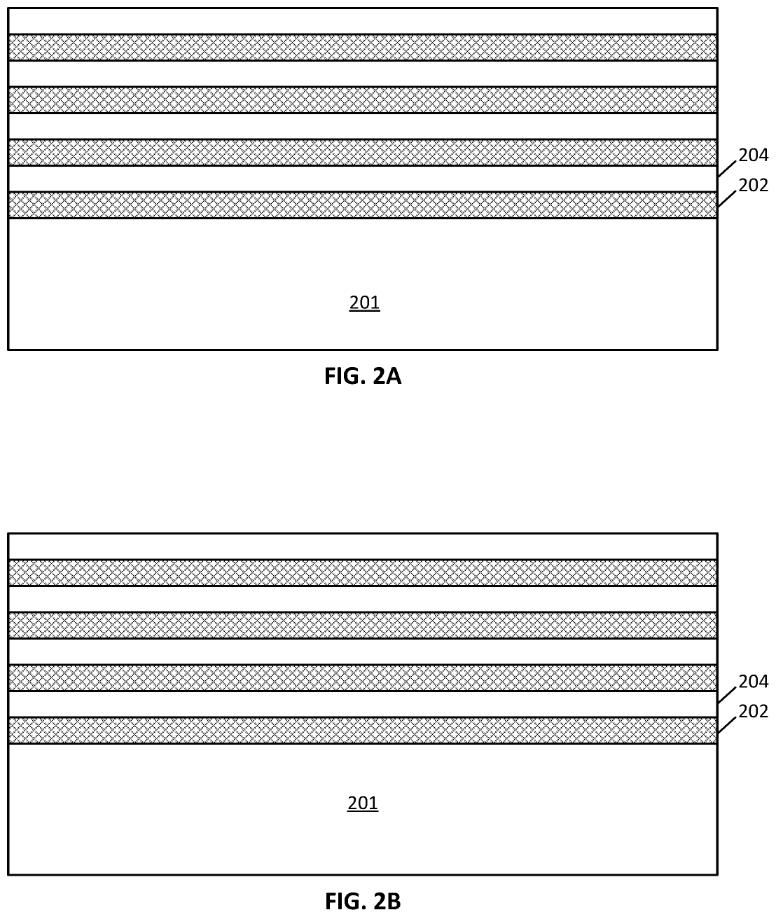

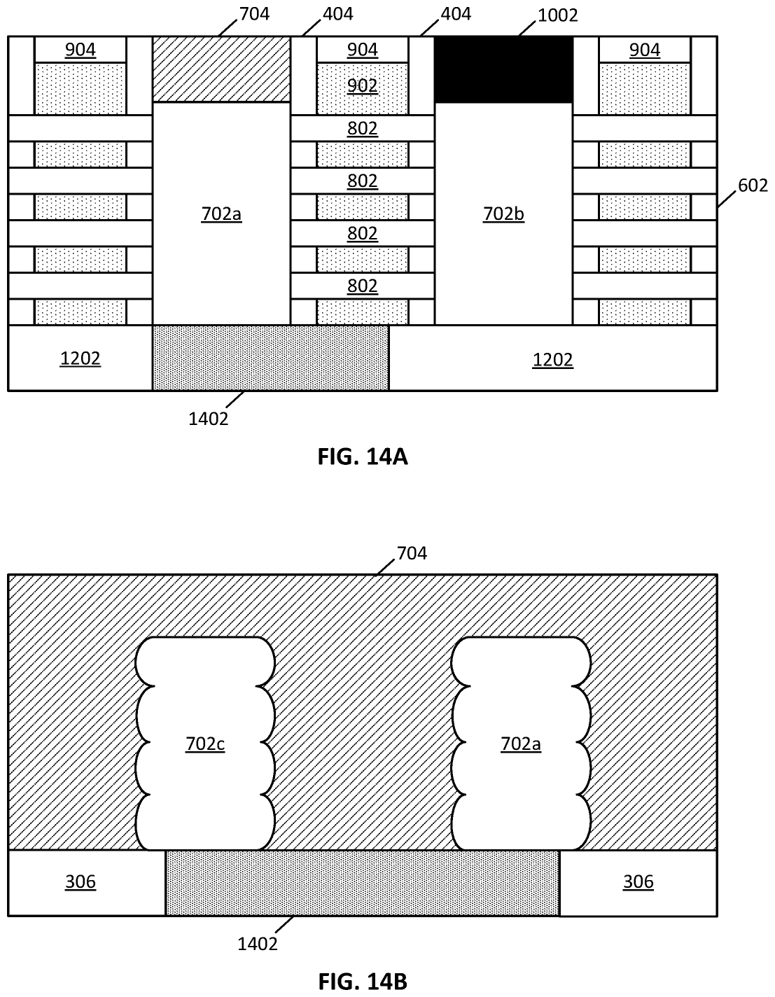

FIGS. 2A-14A and 2B-14B include cross-sectional views that collectively illustrate an example process for forming an integrated circuit configured with a backside conductive layer coupled between different source or drain regions, in accordance with an embodiment of the present disclosure. FIGS. 2A-14A represent a similar cross-sectional view taken across the XZ plane in FIG. 1B, while FIGS. 2B-14B represent a cross-sectional view taken across the YZ in FIG. 1C. Each set of figures sharing the same letter shows an example structure that results from the process flow up to that point in time, so the depicted structure evolves as the process flow continues, culminating in the structure shown in FIGS. 14A-14B, which is similar to the structure shown in FIGS. 1B and 1C. Such a structure may be part of an overall integrated circuit (e.g., such as a processor or memory chip) that includes, for example, digital logic cells and/or memory cells and analog mixed signal circuitry. Thus, the illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIGS. 2A and 2B each illustrates a cross-sectional view taken through a substrate 201 having a series of material layers formed over the substrate, according to an embodiment of the present disclosure. Alternating material layers may be deposited over substrate 201 including sacrificial layers 202 alternating with semiconductor layers 204. The alternating layers are used to form GAA transistor structures. Any number of alternating sacrificial layers 202 and semiconductor layers 204 may be deposited over substrate 201.

Substrate 201 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 201 can be a semiconductor-on-insulator substrate having a desired semiconductor layer over a buried insulator layer (e.g., silicon over silicon dioxide). Alternatively, substrate 201 can be a multilayer substrate or superlattice suitable for forming nanowires or nanoribbons (e.g., alternating layers of silicon and SiGe, or alternating layers indium gallium arsenide and indium phosphide). Any number of substrates can be used.

According to some embodiments, semiconductor layers 204 have a different material composition than sacrificial layers 202. In some embodiments, semiconductor layers 204 are silicon germanium (SiGe) while sacrificial layers 202 include a semiconductor material suitable for use as a nanoribbon such as silicon (Si), SiGe, germanium, or III-V materials like indium phosphide (InP) or gallium arsenide (GaAs). In examples where SiGe is used in each of semiconductor layers 204 and in sacrificial layers 202, the germanium concentration is different between semiconductor layers 204 and sacrificial layers 202. For example, semiconductor layers 204 may include a higher germanium content compared to sacrificial layers 202.

While dimensions can vary from one example embodiment to the next, the thickness of each semiconductor layer 204 may be between about 5 nm and about 20 nm. In some embodiments, the thickness of each semiconductor layer 204 is substantially the same (e.g., within 1-2 nm). The thickness of each of sacrificial layers 202 may be about the same as the thickness of each semiconductor layer 204 (e.g., about 5-20 nm). Each of semiconductor layers 204 and sacrificial layers 202 may be deposited using any known material deposition technique, such as chemical vapor deposition (CVD), plasma-enhanced chemical vapor deposition (PECVD), physical vapor deposition (PVD), or atomic layer deposition (ALD), or epitaxial growth.

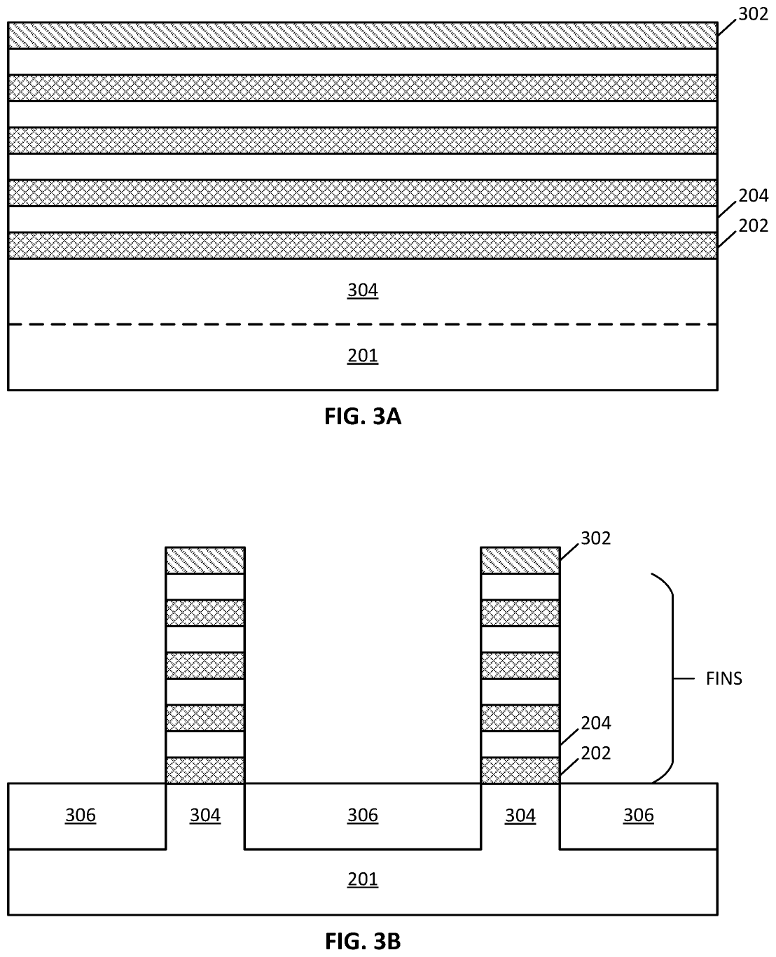

FIGS. 3A and 3B depict the cross-section views of the structure shown in FIGS. 2A and 2B, respectively, following the formation of a cap layer 302 and the subsequent formation of fins beneath cap layer 302, according to an embodiment. Cap layer 302 may be any suitable hard mask material such as a carbon hard mask (CHM) or silicon nitride. Cap layer 302 is patterned into rows to form corresponding rows of fins from the alternating layer stack of sacrificial layers 202 and semiconductor layers 204. Cap layer 302 extends along the top of each fin in a first direction, as seen in FIG. 3A.

According to some embodiments, an anisotropic etching process through the layer stack continues into at least a portion of substrate 201. Portions of substrate 201 beneath the fins are not etched and yield subfin regions 304. The etched portion of substrate 201 may be filled with a dielectric layer 306 that acts as shallow trench isolation (STI) between adjacent fins. Dielectric layer 306 may be any suitable dielectric material such as silicon oxide. Subfin regions 304 represent remaining portions of substrate 201 between dielectric layer 306, according to some embodiments.

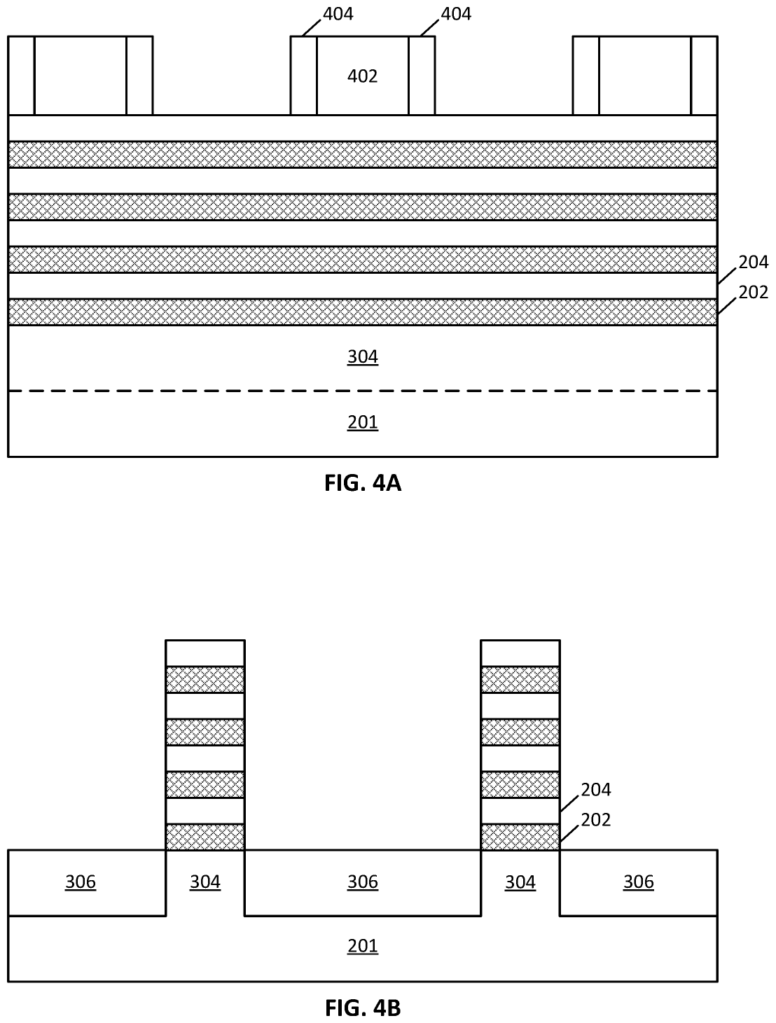

FIGS. 4A and 4B depict cross-section views of the structures shown in FIGS. 3A and 3B following the formation of sacrificial gates 402, according to some embodiments. A gate masking layer may first be patterned in strips that extend orthogonally across each of the fins (e.g., in a second direction) in order to form corresponding sacrificial gates 402 in strips beneath the gate masking layers. Afterwards, the gate masking layers may be removed or may remain as a cap layer above each sacrificial gate 402. According to some embodiments, the sacrificial gate material is removed in all areas not protected by the gate masking layers. Sacrificial gate 402 may be any suitable material that can be selectively removed without damaging the semiconductor material of the fins. In some examples, sacrificial gate 402 includes polysilicon.

According to some embodiments, spacer structures 404 are formed along the sidewalls of sacrificial gates 402. Spacer structures 404 may be deposited and then etched back such that spacer structures 404 remain mostly only on sidewalls of any exposed structures. In the cross-section view of FIG. 4B, spacer structures 404 may also be formed along sidewalls of the exposed fins over dielectric layer 306. Such sidewall spacers on the fins can be removed during later processing when forming the source or drain regions. According to some embodiments, spacer structures 404 may be any suitable dielectric material, such as silicon nitride, silicon carbon nitride, or silicon oxycarbonitride. In one such embodiment, spacer structures 404 comprise a nitride and dielectric layer 306 comprises an oxide, so as to provide a degree of etch selectivity during final gate processing. Other etch selective dielectric schemes (e.g., oxide/carbide, carbide/nitride) can be used as well for spacer structures 404 and dielectric layer 306. In other embodiments, spacer structures 404 and dielectric layer 306 are compositionally the same or otherwise similar, where etch selectivity is not employed.

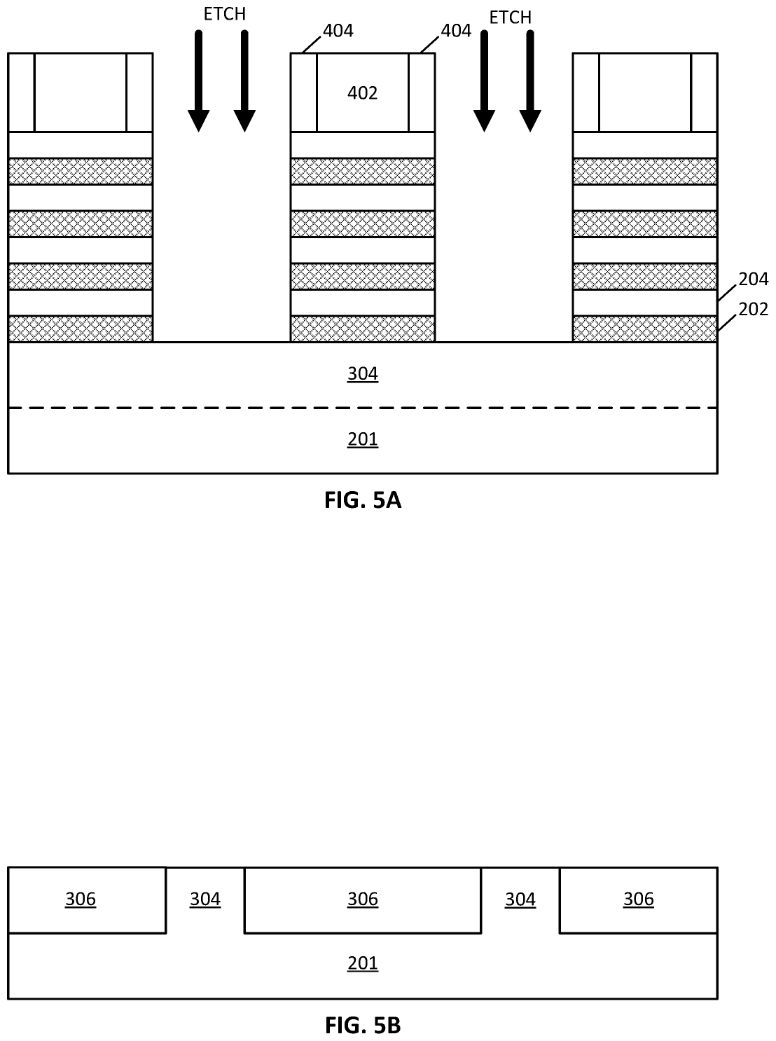

FIGS. 5A and 5B depict cross-section views of the structures shown in FIGS. 4A and 4B following the removal of exposed portions of the fins not protected by sacrificial gates 402 and spacer structures 404, according to some embodiments. The exposed fin portions may be removed using any anisotropic etching process, such as reactive ion etching (RIE). The removal of the exposed fin portions creates source or drain trenches that alternate with gate trenches (currently filled with sacrificial gates 402) along the first direction, according to some embodiments.

According to some embodiments, a portion of substrate 201 is also removed during the etching process to form recessed regions below a top surface of substrate 201. In some examples, at least a portion of subfin regions 304 are removed such that a top surface of subfin regions 304 is recessed below a top surface of dielectric layer 306. In some examples, sacrificial plugs may be formed within the etched recesses to be removed later during the formation of backside contacts. In some examples, the eventual source or drain regions may extend below the top surface of the subfin regions 304 when the top surface of subfin regions 304 is recessed below the top surface of dielectric layer 306.

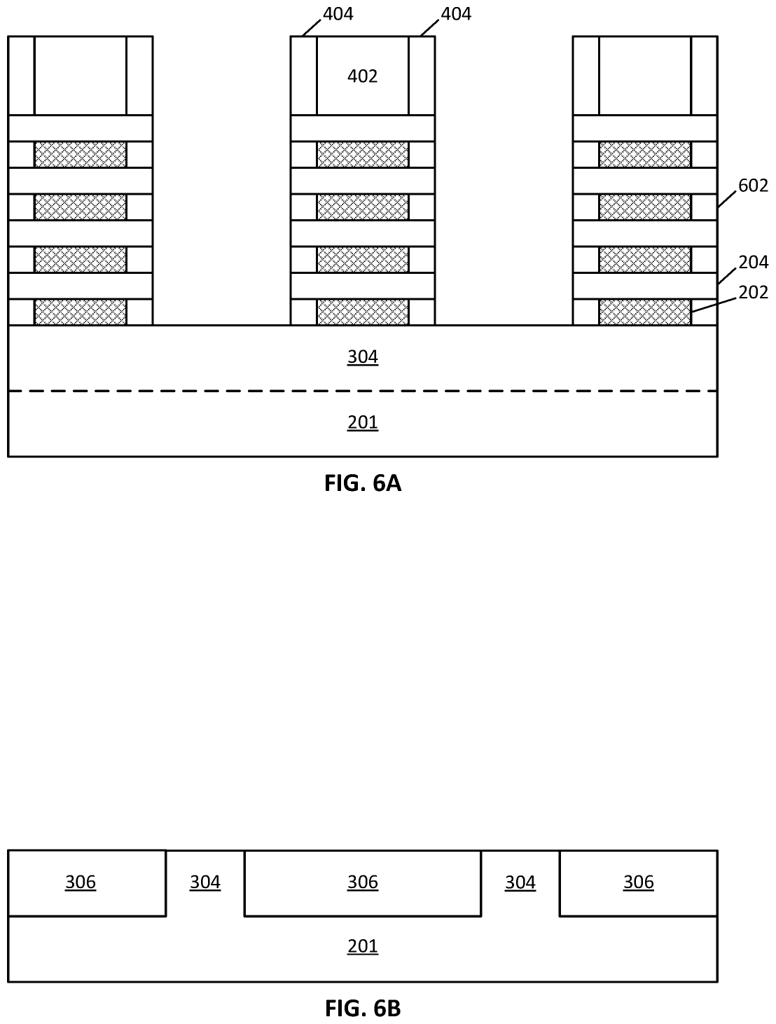

FIGS. 6A and 6B depict cross-section views of the structures shown in FIGS. 5A and 5B following the removal of portions of sacrificial layers 202 and subsequent formation of internal spacers 602, according to an embodiment of the present disclosure. An isotropic etching process may be used to selectively recess the exposed ends of each sacrificial layer 202 (e.g., while etching comparatively little of semiconductor layers 204). Internal spacers 602 may have a material composition that is similar to or the exact same as spacer structures 404. Accordingly, internal spacers 602 may be any suitable dielectric material that exhibits high etch selectively to semiconductor materials such as silicon and/or silicon germanium. Internal spacers 602 may be, for example, conformally deposited over the sides of the fin structure using a conformal deposition process like CVD or ALD and then etched back using an isotropic etching process to expose the ends of semiconductor layers 204. According to some embodiments, internal spacers 602 have a similar width (e.g., along the first direction) to spacer structures 404.

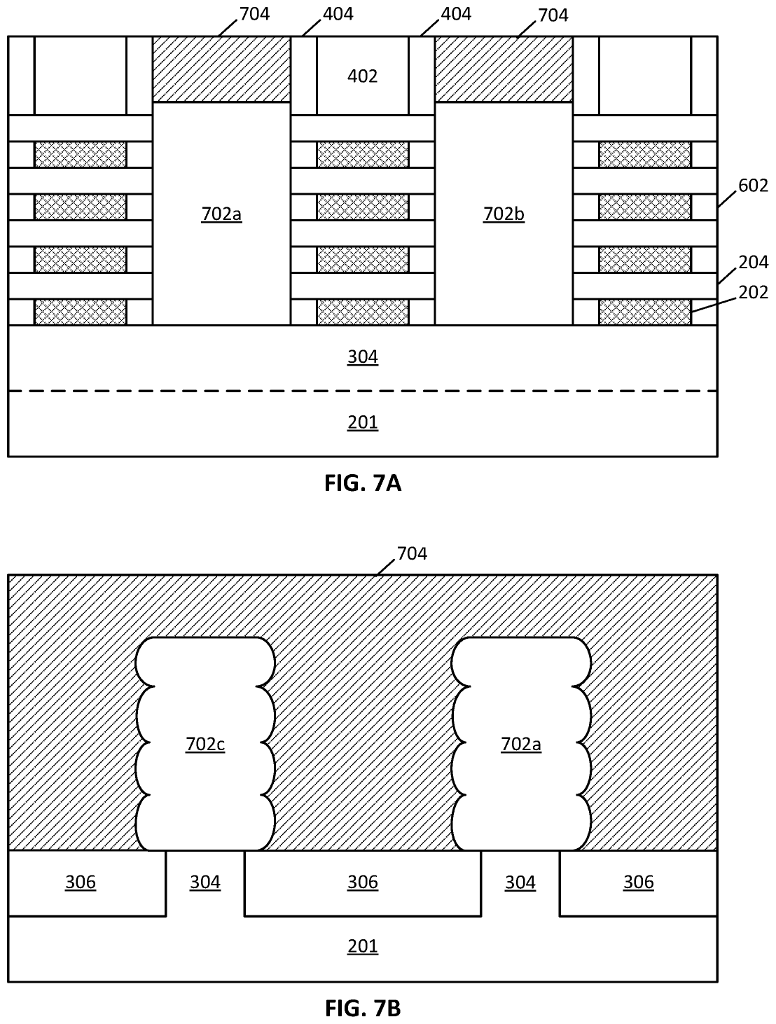

FIGS. 7A and 7B depict cross-section views of the structure shown in FIGS. 6A and 6B, respectively, following the formation of source or drain regions 702 within the source/drain trenches, according to some embodiments. The source or drain regions may be formed in the areas that had been previously occupied by the exposed fins between spacer structures 404. According to some embodiments, a first semiconductor device includes a first source or drain region 702a and a second source or drain region 702b as illustrated in FIG. 7A. First source or drain region 702a is also seen in the orthogonal cross-section of FIG. 7B and is adjacent to a third source or drain region 702c from a second semiconductor device.

According to some embodiments, source or drain regions 702 are epitaxially grown from the exposed semiconductor material at the ends of semiconductor layers 204. In some example embodiments, first and second source or drain regions 702a/702b are NMOS source or drain regions (e.g., epitaxial silicon), and third source or drain region 702c is a PMOS source or drain region (e.g., epitaxial SiGe). As noted above, each of source or drain regions 702 may extend below the top surface of subfin region 304 as illustrated in FIG. 7A (and below the top surface of dielectric layer 306 as illustrated in FIG. 7B).

According to some embodiments, a dielectric fill 704 is provided within the source/drain trench. In some examples, dielectric fill 704 occupies a remaining volume within the source/drain trench around and over source or drain regions 702. Dielectric fill 704 may be any suitable dielectric material, such as silicon dioxide. In some examples, dielectric fill 704 extends up to and planar with a top surface of spacer structures 404 (e.g., following a polishing procedure) as seen in FIG. 7A.

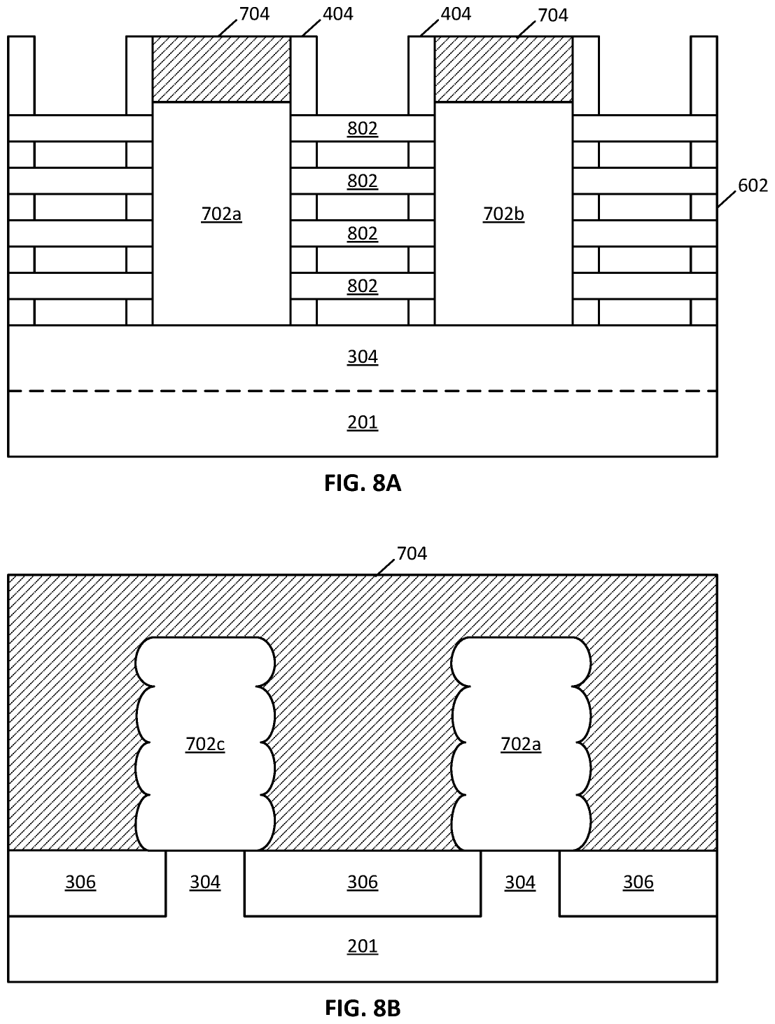

FIGS. 8A and 8B depict cross-section views of the structure shown in FIGS. 7A and 7B, respectively, following the removal of sacrificial gates 402 and sacrificial layers 202, according to some embodiments. In examples where gate masking layers are still present, they would be removed at this time. Once sacrificial gates 402 are removed, the fins extending between spacer structures 404 are exposed.

In the example where the fins include alternating semiconductor layers, sacrificial layers 202 are selectively removed to leave behind nanoribbons 802 that extend between corresponding source or drain regions (such as between first source or drain region 702a and second source or drain region 702b). Each vertical set of nanoribbons 802 represents the semiconductor region of a different semiconductor device. It should be understood that nanoribbons 802 may also be nanowires or nanosheets. Sacrificial gates 402 and sacrificial layers 202 may be removed using the same isotropic etching process or different isotropic etching processes.

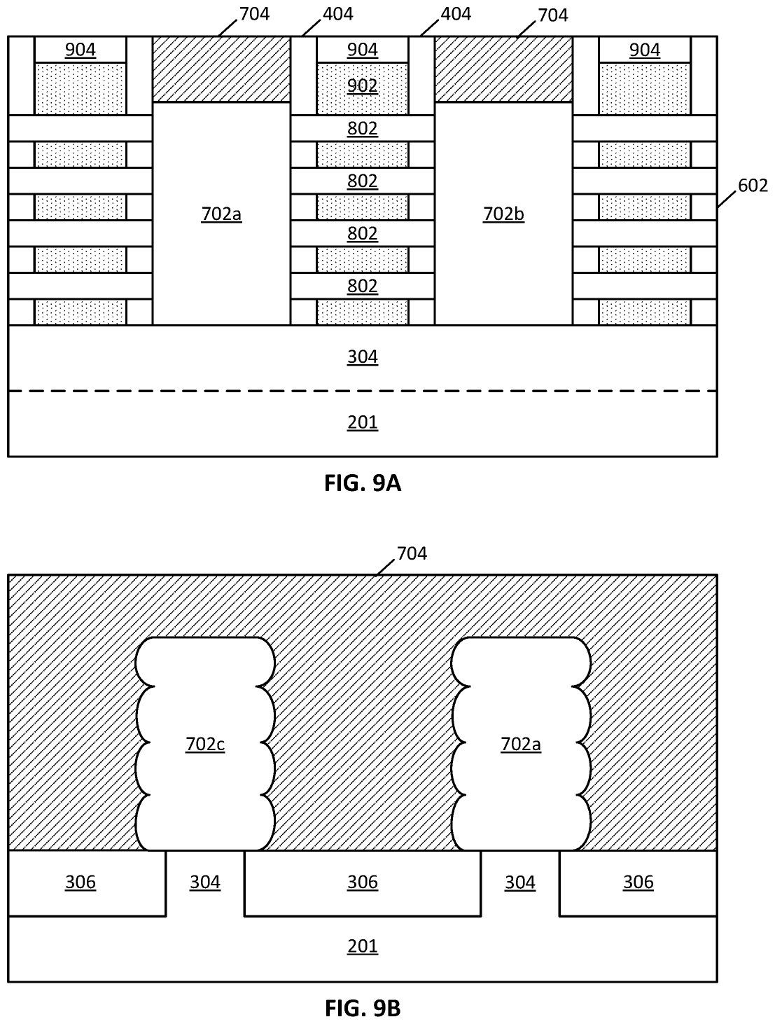

FIGS. 9A and 9B depict cross-section views of the structure shown in FIGS. 8A and 8B, respectively, following the formation of a gate structure 902, which includes a gate dielectric and a gate electrode, and a subsequent gate cap 904, according to some embodiments. The gate dielectric may be first formed around nanoribbons 802 prior to the formation of the gate electrode, which may include one or more conductive layers. The gate dielectric may include any suitable dielectric material (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric includes a layer of hafnium oxide with a thickness between about 1 nm and about 5 nm. In some embodiments, the gate dielectric may include one or more silicates (e.g., titanium silicate, tungsten silicate, niobium silicate, and silicates of other transition metals). In some cases, the gate dielectric includes a first layer on nanoribbons 802, and a second layer on the first layer. The first layer can be, for instance, an oxide of the semiconductor material of nanoribbons 802 (e.g., silicon dioxide) and the second layer can be a high-k dielectric material (e.g., hafnium oxide).

The one or more conductive layers that make up the gate electrode may be deposited using electroplating, electroless plating, CVD, PECVD, ALD, or PVD, to name a few examples. In some embodiments, the gate electrode includes doped polysilicon, a metal, or a metal alloy. Example suitable metals or metal alloys include aluminum, tungsten, cobalt, molybdenum, ruthenium, titanium, tantalum, copper, and carbides and nitrides thereof. The gate electrode may include, for instance, a metal fill material along with one or more workfunction layers, resistance-reducing layers, and/or barrier layers. The workfunction layers can include, for example, p-type workfunction materials (e.g., titanium nitride) for PMOS gates, or n-type workfunction materials (e.g., titanium aluminum carbide) for NMOS gates.

Gate cap 904 may be formed by first recessing the gate electrode and filling the recess with a dielectric material. The dielectric material may then be polished such that its top surface is substantially coplanar with a top surface of spacer structures 404 and/or dielectric fill 704. In some embodiments, gate structure 902 may extend below the top surface of subfin region 304 within the gate trench.

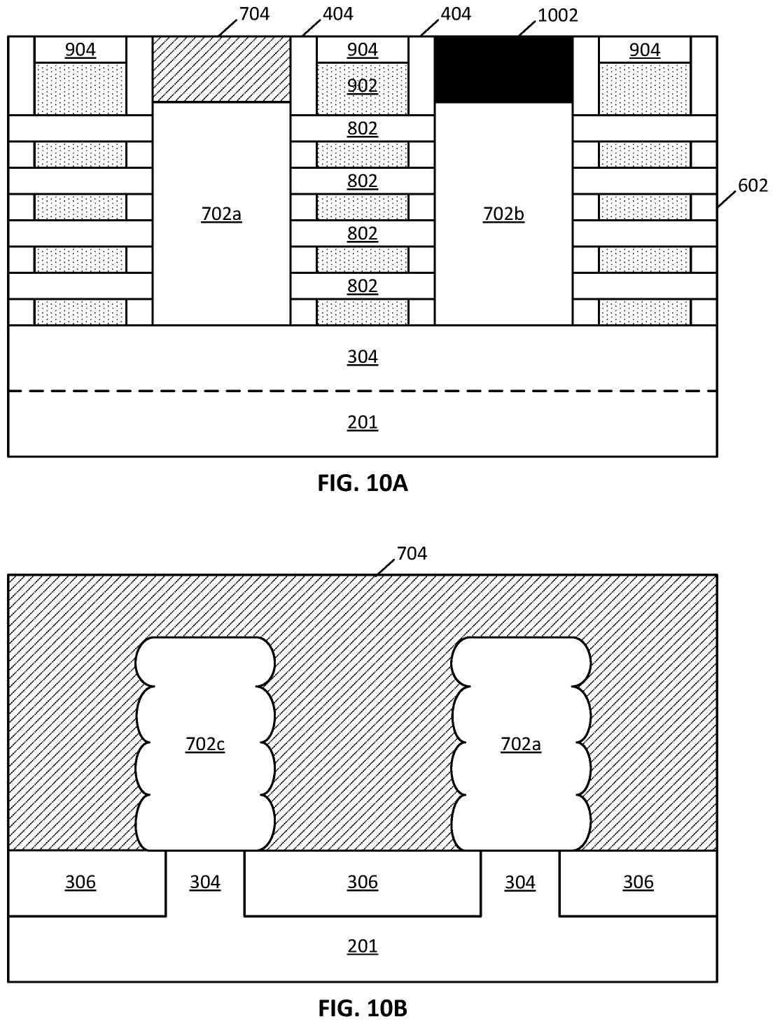

FIGS. 10A and 10B depict cross-section views of the structure shown in FIGS. 9A and 9B, respectively, following the formation of a frontside conductive contact 1002 within the source/drain trench and on any number of source or drain regions, according to some embodiments. In the illustrated example, a single frontside conductive contact 1002 is formed over second source or drain region 702b. Frontside conductive contact 1002 may include any suitable conductive material, such as tungsten, molybdenum, ruthenium, or cobalt for making electrical contact with the underlying second source or drain region 702b. As seen in the cross section of FIG. 10A, a portion of dielectric fill 704 is recessed to expose at least the top surface of second source or drain region 702b and frontside conductive contact 1002 is formed within the recess using any suitable metal deposition process. According to some embodiments, frontside conductive contact 1002 includes one or more silicide layers directly on the exposed surface of second source or drain region 702b.

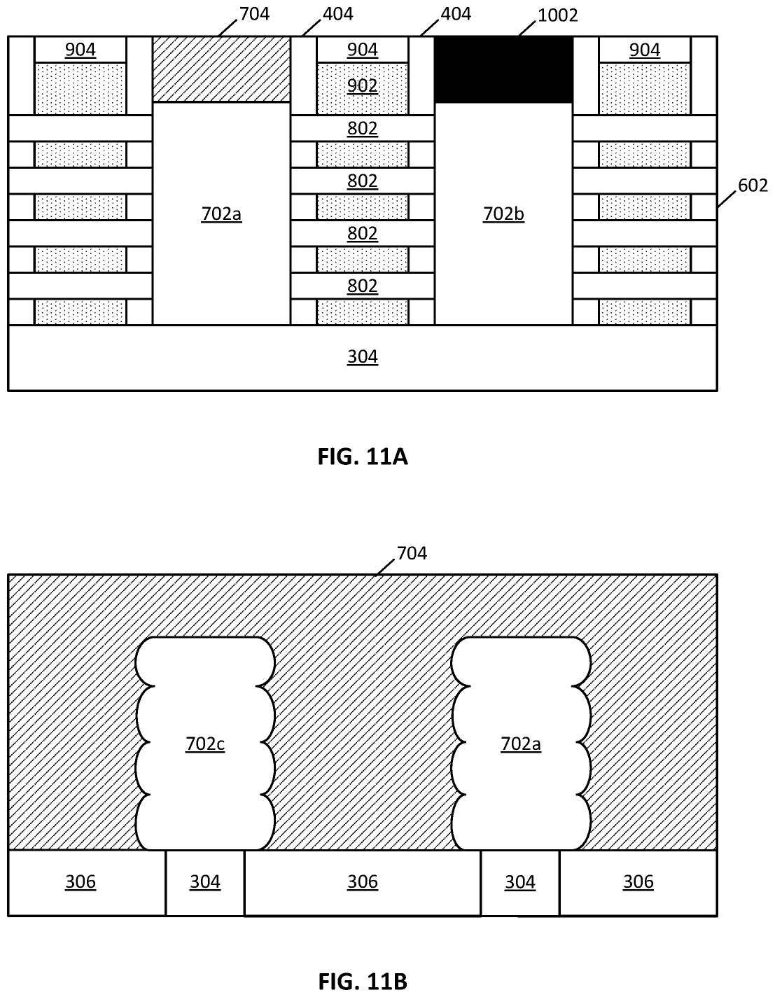

FIGS. 11A and 11B depict cross-section views of the structure shown in FIGS. 10A and 10B, respectively, following the removal of a bulk portion of substrate 201, according to some embodiments. Substrate 201 may be removed from the backside via any combination of grinding, polishing, and/or etching processes. In some embodiments, substrate 201 may continue to be thinned from the backside until bottom surfaces of dielectric layer 306 or subfin regions 304 are exposed. In some examples, the backside polishing process may continue until at least both bottom surfaces of dielectric layer 306 and subfin regions 304 are exposed.

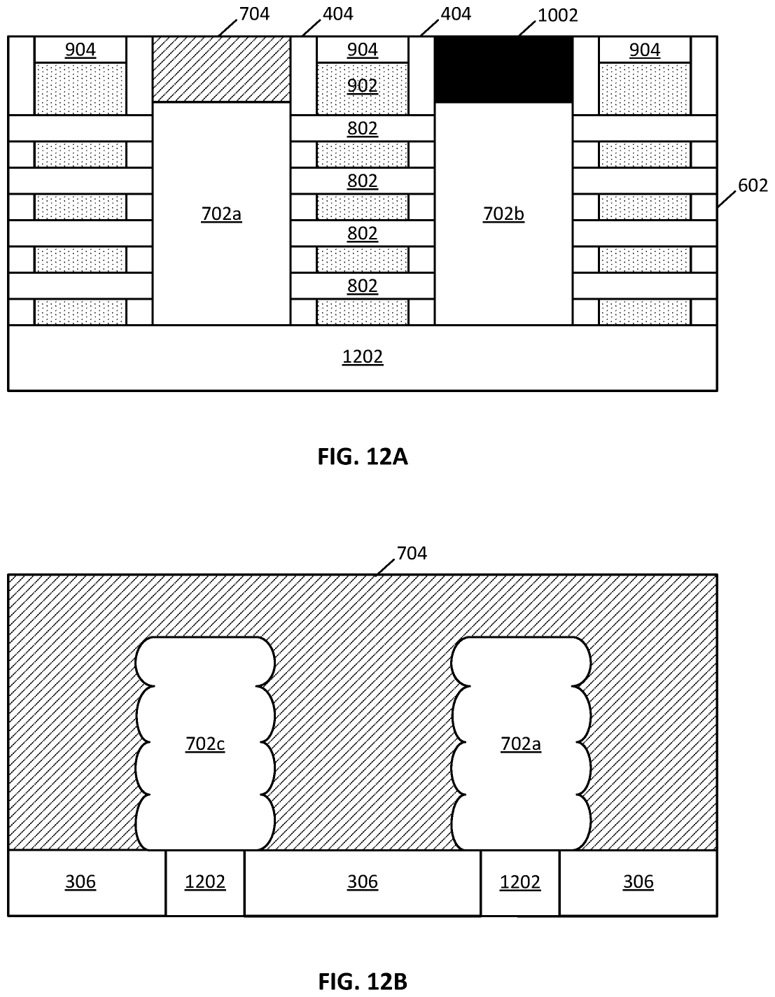

FIGS. 12A and 12B depict cross-section views of the structure shown in FIGS. 11A and 11B, respectively, following the removal of subfin regions 304 and subsequent formation of backside dielectric layer 1202, according to some embodiments. An isotropic etching process may be used to remove the exposed semiconductor material of subfin regions 304. The areas left behind following this removal of subfin regions 304 may then be filled with dielectric material to form backside dielectric layer 1202. In some embodiments, backside dielectric layer 1202 includes the same material as dielectric layer 306, such that there is little to no discernable difference between them. Backside dielectric layer 1202 may be any suitable dielectric material, such as silicon dioxide, silicon nitride, or silicon oxynitride. According to some embodiments, backside dielectric layer 1202 is polished following its deposition such that a bottom surface of backside dielectric layer 1202 is substantially coplanar with a bottom surface of dielectric layer 306.

It should be noted that in some embodiments, portions of subfin regions 304 may remain beneath nanoribbons 802 following the formation of backside dielectric layer 1202. This can occur in examples where source or drain regions 702 extend below the top surface of the subfin regions 304 and where portions of gate structure 902 extend below the top surface of the subfin regions 304. The existence of any remaining portions of subfin regions 304 does not change the remaining fabrication processes to form the backside interconnects.

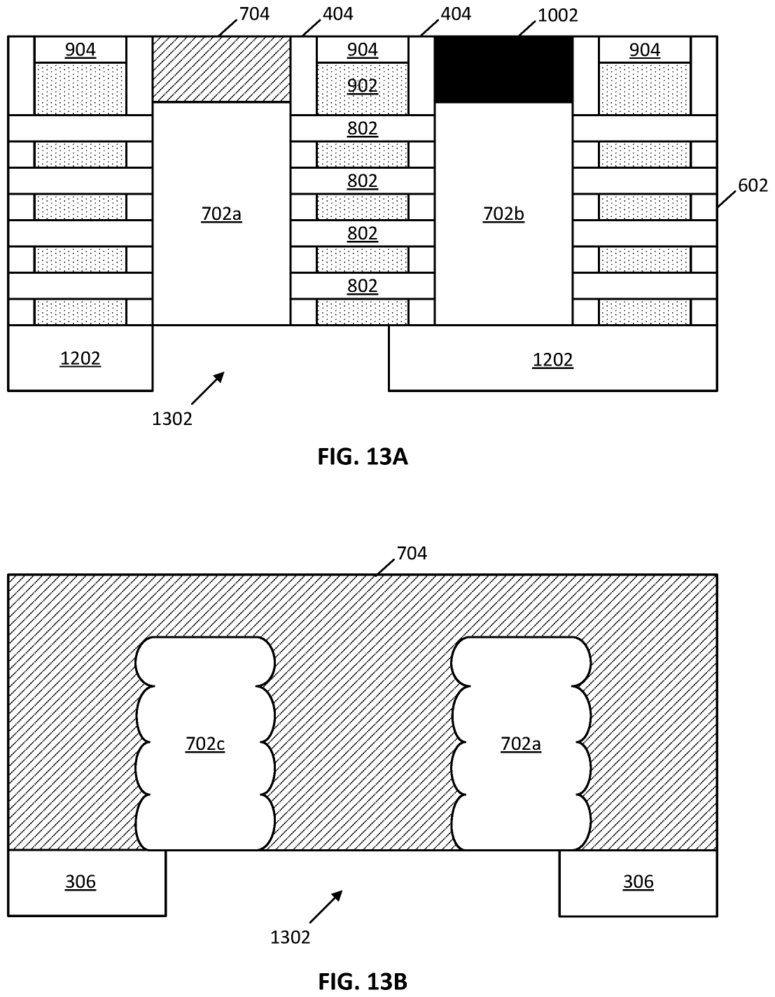

FIGS. 13A and 13B depict cross-section views of the structure shown in FIGS. 12A and 12B, respectively, following the formation of backside recess 1302 through backside dielectric layer 1202 and dielectric layer 306, according to some embodiments. Backside recess 1302 may be formed using an RIE process to etch away portions of backside dielectric layer 1202 and dielectric layer 306 to expose the underside of various transistor elements. In the illustrated example, an ‘L’ shaped backside recess 1302 exposes the bottom surface of first source or drain region 702a, the bottom surface of third source or drain region 702c, and the bottom surface of gate structure 902. The gate dielectric may be first exposed on the bottom of the gate electrode of gate structure 902, and removed using any suitable isotropic etching process if it is not already removed during the RIE process, such that the gate electrode is exposed. Backside recess 1302 extends through an entire thickness of backside dielectric layer 1202 and/or dielectric layer 306.

FIGS. 14A and 14B depict cross-section views of the structure shown in FIGS. 13A and 13B, respectively, following the formation of a backside interconnect 1402, according to some embodiments. Backside interconnect 1402 may be formed within backside recess 1302 and on the bottom surfaces of various transistor elements, thus conductively connecting them together. In the illustrated example, backside interconnect 1402 contacts the bottom surfaces of first source or drain region 702a, third source or drain region 702c, and gate structure 902. Accordingly, backside interconnect 1402 may include a first section extending in the first direction (as seen in FIG. 14A) and a second section extending in the second direction (as seen in FIG. 14B) with both sections connected at a common point beneath first source or drain region 702a. Backside interconnect 1402 may include any suitable conductive material, such as tungsten, molybdenum, ruthenium, or cobalt. A bottom surface of backside interconnect 1402 may be polished using any known polishing technique (e.g., chemical mechanical polishing), such that it is substantially coplanar with a bottom surface of backside dielectric layer 1202 and/or dielectric layer 306. Backside interconnect 1402 may include both a conductive liner along edges of the structure and a conductive fill on the conductive liner. The conductive liner may include a barrier layer and/or an adhesion layer and may be titanium nitride or tantalum nitride. In some embodiments, the conductive liner includes a silicide layer (e.g., titanium silicide, nickel silicide, platinum silicide, cobalt silicide, or any of their ternary silicide) at least at the interface between backside interconnect 1402 and source or drain regions 702a and 702c. In some embodiments, the barrier layer is formed on the silicide layer and the remaining conductive fill is formed on the barrier layer. The conductive fill includes any of tungsten, molybdenum, ruthenium, or cobalt.

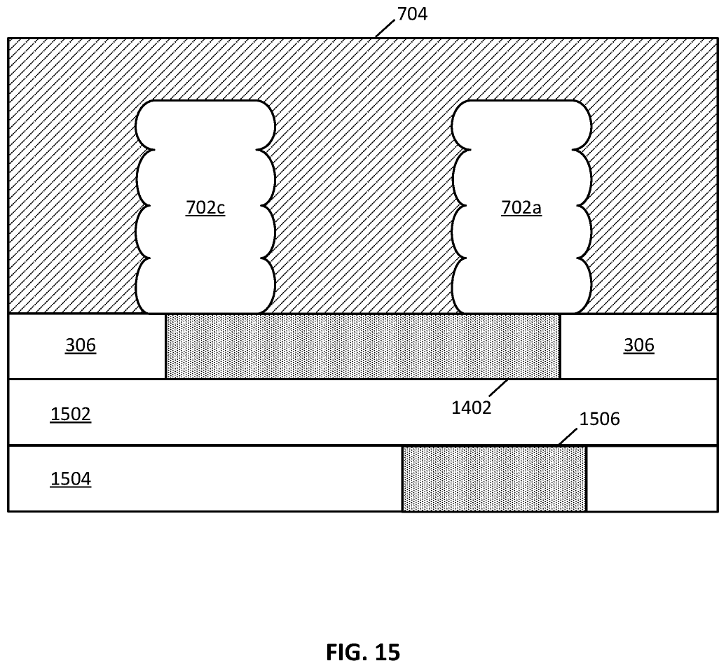

According to some embodiments, backside interconnect 1402 may be one conductive element of a first backside interconnect layer. Additional backside interconnect layers may be formed beneath backside interconnect 1402 to provide other electrical connections to the backside of other transistor elements, such as power and ground rails. FIG. 15 illustrates an example of the structure shown in FIG. 14B with a second backside dielectric layer 1502, a third backside dielectric layer 1504, and a backside conductive layer 1506, according to some embodiments. Each of second backside dielectric layer 1502 and third backside dielectric layer 1504 may be any suitable dielectric material, and may be the same dielectric material as backside dielectric layer 1202 and/or dielectric layer 306. Backside conductive layer 1506 may include any suitable conductive material, such as tungsten, tungsten nitride, titanium, titanium nitride, tantalum, ruthenium, molybdenum, cobalt, or copper along with a suitable barrier layer. The barrier layer may include tantalum nitride, ruthenium tantalum nitride, or titanium nitride.

According to some embodiments, backside conductive layer 1506 may be used to supply a power or ground rail to the semiconductor devices. The presence of backside interconnect 1402 relegates backside conductive layer 1506 to a lower position within the backside interconnect region to avoid any shorting between the conductive layers, according to some embodiments. Any source or drain region may be coupled to backside conductive layer 1506 using one or more vias that pass through the thickness of each of backside dielectric layer 1202/dielectric layer 306, and second backside dielectric layer 1502.

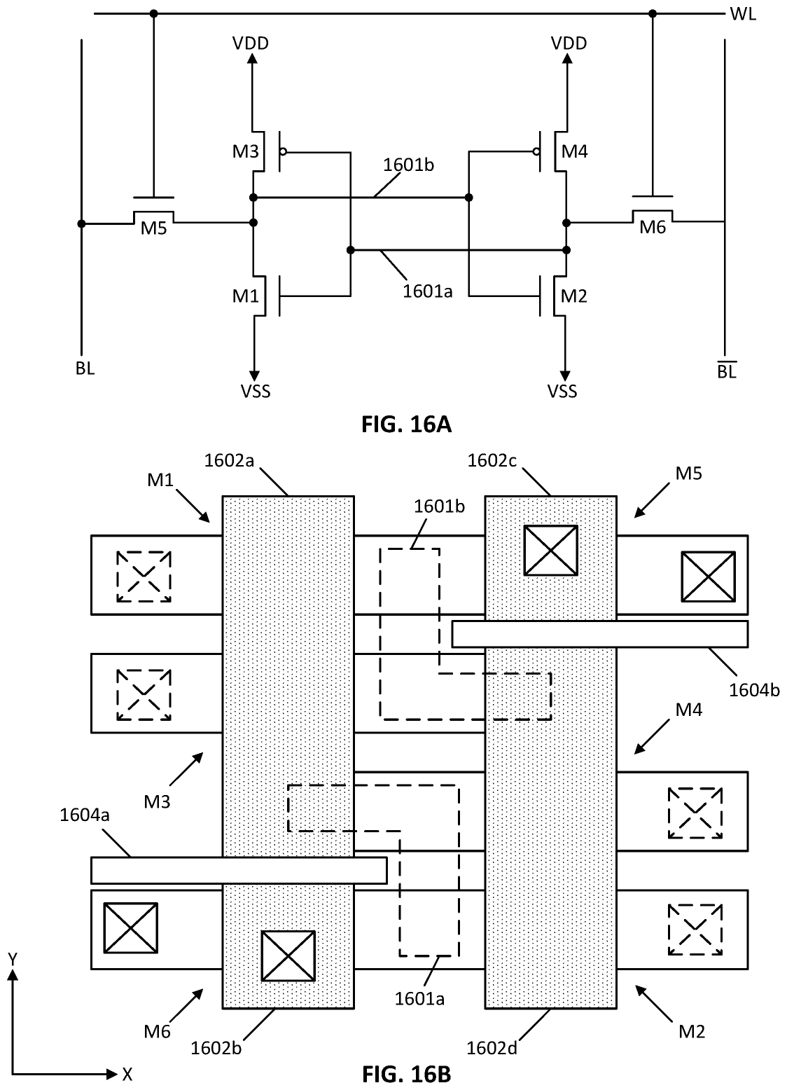

Backside interconnects may be used to create cross-couple backside connections in circuits that require coupling between gates of one or more transistors to the source or drain regions of one or more different transistors. This situation occurs for an SRAM cell where two cross-coupled connections are used within the circuit. FIG. 16A is a circuit schematic of a standard SRAM cell and FIG. 16B illustrates a transistor layout using backside cross-coupled connections that may be used to fabricate the SRAM cell circuit of FIG. 16A, according to some embodiments. As can be seen in this example, the SRAM cell includes six transistors (M1-M6) to provide a 6T SRAM cell, with four memory transistors arranged as flip-flops broken into two n-type transistors (M1 and M2) and two p-type transistors (M3 and M4), and two n-type access transistors (M5 and M6). In the flip-flop arrangement, the gates of M1 and M3 are coupled together and are also coupled to a common source/drain terminal between M2 and M4 using a first cross-couple interconnect 1601a. Similarly, the gates of M2 and M4 are coupled together and are also coupled to a common source/drain terminal between M1 and M3 using a second cross-couple interconnect 1601b. Access transistor M5 is coupled between the common source/drain terminal between M1 and M3 and a first bitline BL while access transistor M6 is coupled between the common source/drain terminal between M1 and M3 and a second bitline B̅L̅. The gates of each access transistor M5 and M6 are coupled to a wordline WL. First cross-couple interconnect 1601a and second cross-couple interconnect 1601b can be complicated to arrange using traditional topside interconnect methods. Accordingly, providing these cross-couple interconnects on the backside of the structure frees up more room for interconnect routing on the topside.

The layout of the SRAM cell from FIG. 16A is shown in FIG. 16B with the same six transistors M1-M6 arranged across four gate trenches (1602a-1602d). Note in this example that M3 and M4 are p-channel transistors while M1, M2, M5, and M6 are n-channel transistors. The first gate trench 1602a is colinearly aligned with the second gate trench 1602b along the Y-direction and separated from the second gate trench 1602b by a first dielectric gate cut 1604a. The third gate trench 1602c is colinearly aligned with the fourth gate trench 1602d along the Y-direction and separated from the fourth gate trench 1602d by a second dielectric gate cut 1604b. More than one transistor gate may be present in a given gate trench, and thus conductively coupled together. In the illustrated example, the gates of M1 and M3 are coupled together within first gate trench 1602a and the gates of M2 and M4 are coupled together within fourth gate trench 1602d.

Topside contacts to transistor elements are provided with solid lines while backside contacts and interconnects to transistor elements are provided with dashed lines. According to some embodiments, backside ‘L’ shaped interconnects, similar to those described above with reference to FIGS. 14A and 14B, are used to provide the cross-coupled interconnects 1601a and 1601b. First cross-coupled interconnect 1601a contacts the underside of a source or drain region shared by both M2 and M6, the underside of a source or drain region of M4, and the underside of at least a portion of first gate trench 1602a. Accordingly, first cross-coupled interconnect 1601a provides the connection between source or drain regions of M2, M4, and M6 and the gates of M1 and M3. Second cross-coupled interconnect 1601b contacts the underside of a source or drain region shared by both M1 and M5, the underside of a source or drain region of M3, and the underside of at least a portion of fourth gate trench 1602d. Accordingly, second cross-coupled interconnect 1601b provides the connection between source or drain regions of M1, M3, and M5 and the gates of M2 and M4. Backside power and ground rails may also be provided via backside contacts to the other source or drain region of transistors M1, M2, M3, and M4. Providing the cross-couple connections on the backside frees up more room on the topside for routing the bitline and wordline interconnects to the topside contacts shown on the other source or drain regions of M5 and M6, and on the gates of M5 and M6.

While the examples of FIGS. 16A-B are with respect to an SRAM cell, the techniques described herein can readily be applied to other memory cell types (e.g., multi-port DRAM cell), or logic cells (e.g., transistor-to-transistor logic or TTL circuits), or other electronic circuits that includes multiple transistors closely coupled with one another in a functional arrangement in a cell-like fashion.

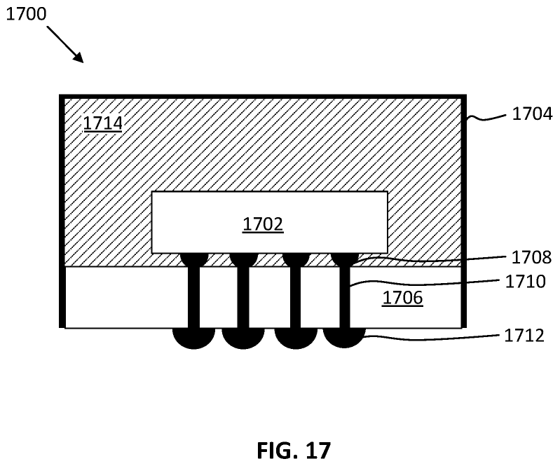

FIG. 17 illustrates an example embodiment of a chip package 1700, in accordance with an embodiment of the present disclosure. As can be seen, chip package 1700 includes one or more dies 1702. One or more dies 1702 may include at least one integrated circuit having semiconductor devices, such as any of the semiconductor devices disclosed herein. One or more dies 1702 may include any other circuitry used to interface with other devices formed on the dies, or other devices connected to chip package 1700, in some example configurations.

As can be further seen, chip package 1700 includes a housing 1704 that is bonded to a package substrate 1706. The housing 1704 may be any standard or proprietary housing, and may provide, for example, electromagnetic shielding and environmental protection for the components of chip package 1700. The one or more dies 1702 may be conductively coupled to a package substrate 1706 using connections 1708, which may be implemented with any number of standard or proprietary connection mechanisms, such as solder bumps, ball grid array (BGA), pins, or wire bonds, to name a few examples. Package substrate 1706 may be any standard or proprietary package substrate, but in some cases includes a dielectric material having conductive pathways (e.g., including conductive vias and lines) extending through the dielectric material between the faces of package substrate 1706, or between different locations on each face. In some embodiments, package substrate 1706 may have a thickness less than 1 millimeter (e.g., between 0.1 millimeters and 0.5 millimeters), although any number of package geometries can be used. Additional conductive contacts 1712 may be disposed at an opposite face of package substrate 1706 for conductively contacting, for instance, a printed circuit board (PCB). One or more vias 1710 extend through a thickness of package substrate 1706 to provide conductive pathways between one or more of connections 1708 to one or more of contacts 1712. Vias 1710 are illustrated as single straight columns through package substrate 1706 for ease of illustration, although other configurations can be used (e.g., damascene, dual damascene, through-silicon via, or an interconnect structure that meanders through the thickness of package substrate 1706 to contact one or more intermediate locations therein). In still other embodiments, vias 1710 are fabricated by multiple smaller stacked vias, or are staggered at different locations across package substrate 1706. In the illustrated embodiment, contacts 1712 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 1712, to inhibit shorting.

In some embodiments, a mold material 1714 may be disposed around the one or more dies 1702 included within housing 1704 (e.g., between dies 1702 and package substrate 1706 as an underfill material, as well as between dies 1702 and housing 1704 as an overfill material). Although the dimensions and qualities of the mold material 1714 can vary from one embodiment to the next, in some embodiments, a thickness of mold material 1714 is less than 1 millimeter. Example materials that may be used for mold material 1714 include epoxy mold materials, as suitable. In some cases, the mold material 1714 is thermally conductive, in addition to being electrically insulating.

### Methodology

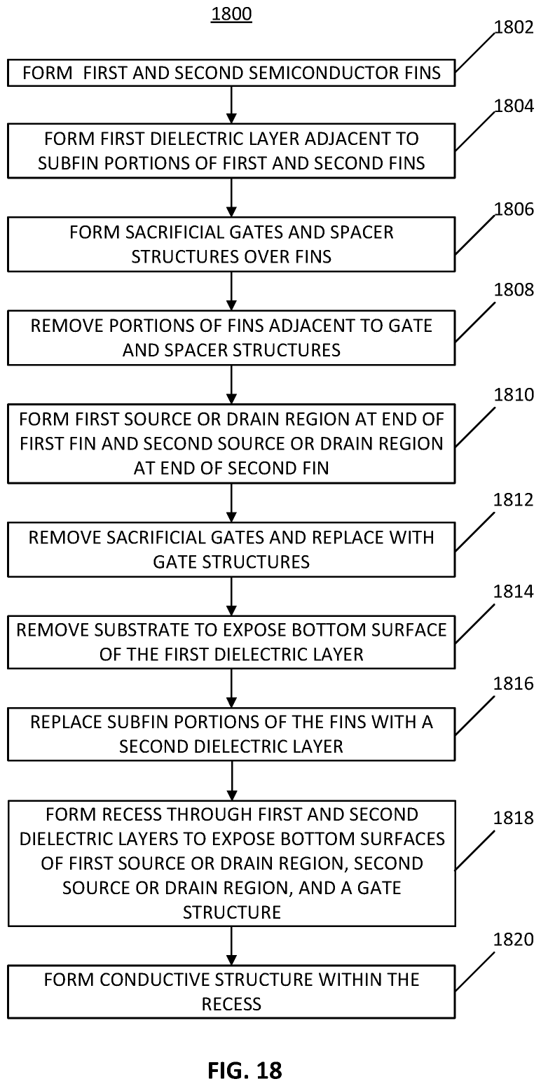

FIG. 18 is a flow chart of a method 1800 for forming at least a portion of an integrated circuit, according to an embodiment. Various operations of method 1800 may be illustrated in FIGS. 2A-14A and 2B-14B. However, the correlation of the various operations of method 1800 to the specific components illustrated in the aforementioned figures is not intended to imply any structural and/or use limitations. Rather, the aforementioned figures provide one example embodiment of method 1800. Other operations may be performed before, during, or after any of the operations of method 1800. For example, method 1800 does not explicitly describe various standard processes that are usually performed to form transistor structures. Some of the operations of method 1800 may be performed in a different order than the illustrated order.

Method 1800 begins with operation 1802 where a plurality of parallel semiconductor fins, including at least a first and second fin, are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, non-native fins can be formed in a so-called aspect ratio trapping based process, where native fins are etched away so as to leave fin-shaped trenches which can then be filled with an alternative semiconductor material (e.g., group IV or III-V material). In still other embodiments, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. Again, the alternating layers can be blanket deposited and then etched into fins, or deposited into fin-shaped trenches. The fins may also include a cap structure over each fin that is used to define the locations of the fins during, for example, an RIE process. The cap structure may be a dielectric material, such as silicon nitride.

Method 1800 continues with operation 1804 where a first dielectric layer is formed adjacent to subfin portions of the first and second fins. The dielectric layer may include any suitable dielectric material, such as silicon dioxide, that is deposited and recessed to a final height around a base subfin portion of the fins. The subfin portion of the fins may be a portion of the substrate that is below the alternating layers of semiconductor material in the case of GAA transistors.

Method 1800 continues with operation 1806 where sacrificial gates are formed over the fins. The sacrificial gates may be patterned using gate masking layers in strips that run orthogonally over the fins and parallel to one another (e.g., forming a cross-hatch pattern). The gate masking layers may be any suitable hard mask material, such as CHM or silicon nitride. The sacrificial gates themselves may be formed from any suitable material that can be selectively removed at a later time without damaging the semiconductor material of the fins. In one example, the sacrificial gates include polysilicon.

According to some embodiments, spacer structures are also formed on sidewalls of at least the sacrificial gates. The spacer structures may be deposited and then etched back such that the spacer structures remain mostly only on sidewalls of any exposed structures. In some cases, spacer structures may also be formed along sidewalls of the exposed fins running orthogonally between the strips of sacrificial gates. According to some embodiments, the spacer structures may be any suitable dielectric material, such as silicon nitride or silicon oxynitride.

Method 1800 continues with operation 1808 where portions of the fins adjacent to the sacrificial gate and spacer structures (e.g., not covered by the sacrificial gate and spacer structures) are removed. Any exposed portions of the fins not covered by the sacrificial gates or spacer structures may be removed using any anisotropic etching process, such as reactive ion etching (RIE). According to some embodiments, the etch continues past the height of the fins into the substrate such that recesses are etched into the substrate between the remaining portions of the fins. The recesses may be filled with one or more dielectric materials or sacrificial materials to facilitate the formation of backside contacts.

Method 1800 continues with operation 1810 where source or drain regions are formed at the exposed ends of the first and second fins, such as a first source or drain region at an end of the first fin and a second source or drain region at an end of the second fin. The source or drain regions may be formed in the areas that had been previously occupied by the exposed fins between the spacer structures. According to some embodiments, the source or drain regions are epitaxially grown from the exposed semiconductor material of the fins (or nanoribbons, nanowires or nanosheets, as the case may be) along the exterior walls of the spacer structures. In some example embodiments, the source or drain regions are NMOS source or drain regions (e.g., epitaxial silicon) or PMOS source or drain regions (e.g., epitaxial SiGe). A dielectric fill may formed between and over the source or drain regions along a given source/drain trench. The dielectric fill may be any suitable dielectric material, such as silicon dioxide. In some examples, the dielectric fill extends over the source or drain regions up to and planar with a top surface of the spacer structures. The dielectric fill also acts as an electrical insulator between adjacent source or drain regions, although some adjacent source or drain regions may have merged together during their growth.

Method 1800 continues with operation 1812 where gate structures are formed over the semiconductor material of the various semiconductor fins. The sacrificial gates are first removed along with any sacrificial layers within the exposed fins between the spacer structures (in the case of GAA structures). The gate structures may then be formed in place of the sacrificial gates. The gate structures may each include both a gate dielectric and a gate electrode. The gate dielectric is first formed over the exposed semiconductor regions between the spacer structures followed by forming the gate electrode within the remainder of the trench between the spacer structures, according to some embodiments. The gate dielectric may include any number of dielectric layers deposited using a CVD process, such as ALD. The gate electrode can include any conductive material, such as a metal, metal alloy, or polysilicon. The gate electrode may be deposited using electroplating, electroless plating, CVD, ALD, PECVD, or PVD, to name a few examples.

According to some embodiments, a portion of the dielectric fill within the source/drain trench may be recessed at least until a top surface of a given source or drain region in the trench is exposed. A frontside conductive contact may be formed within the recess in the source/drain trench such that the frontside conductive contact touches the top surface of given source or drain region in the trench. Separate frontside conductive contacts may be formed within the trench over corresponding source or drain regions, or a frontside conductive contact may extend along the second direction within the trench to contact any number of source or drain regions. The frontside conductive contact may include any suitable conductive material, such as tungsten, molybdenum, ruthenium, or cobalt.

Method 1800 continues with operation 1814 where the substrate is removed from the backside of the structure. The substrate may be removed via any combination of grinding, polishing, and/or etching processes. In some embodiments, the substrate is thinned away at least until a bottom surface of the first dielectric layer is exposed. In some examples, the only portions of the semiconductor material from the substrate left behind following the backside polishing process are the subfin portions adjacent to the first dielectric layer.

Method 1800 continues with operation 1816 where the subfin portions are removed and replaced with a second dielectric layer. The subfin portions may be a semiconductor material (e.g., silicon) that is removed using a suitable isotropic etching process. Once removed, the absence of the subfin regions leaves behind backside recesses that may be filled with one or more suitable dielectric materials to form the second dielectric layer. In some examples, the second dielectric layer is the same dielectric material as the first dielectric layer. The second dielectric layer may be any suitable dielectric material, such as silicon dioxide, silicon nitride, or silicon oxynitride. According to some embodiments, the second dielectric layer is polished following its deposition such that a bottom surface of the second dielectric layer is substantially coplanar with a bottom surface of the first dielectric layer.

Method 1800 continues with operation 1818 where a backside recess is formed through the first and/or second dielectric layers from the backside of the structure. The backside recess may be formed using an RIE process to etch away portions of the first and/or second dielectric layers to expose the underside of the various transistor elements. According to some embodiments, the bottom surface of the first source or drain region, bottom surface of the second source or drain region, and the bottom surface of a gate structure over the semiconductor material of the first and/or second fin are exposed within the recess. In some embodiments, an ‘L’ shaped backside recess is used to connect across adjacent transistor elements along both an x-direction and a y-direction. The backside recess is formed through an entire thickness of the first and/or second dielectric layers.

Method 1800 continues with operation 1820 where a backside conductive structure is formed within the backside recess to conductively contact the underside of various transistor elements. According to some embodiments, the backside conductive structure electrically connects any number of different source or drain regions and/or gate structures together. The backside conductive structure may be used to provide electrical connection between two or more transistor elements regions that are not aligned along the first direction and are not aligned along the second direction. The backside conductive structure may include any suitable conductive material, such as tungsten, molybdenum, ruthenium, or cobalt. A bottom surface of the backside conductive structure may be polished using any known polishing technique (e.g., chemical mechanical polishing), such that it is substantially coplanar with a bottom surface of the first and/or second dielectric layer.

### Example System

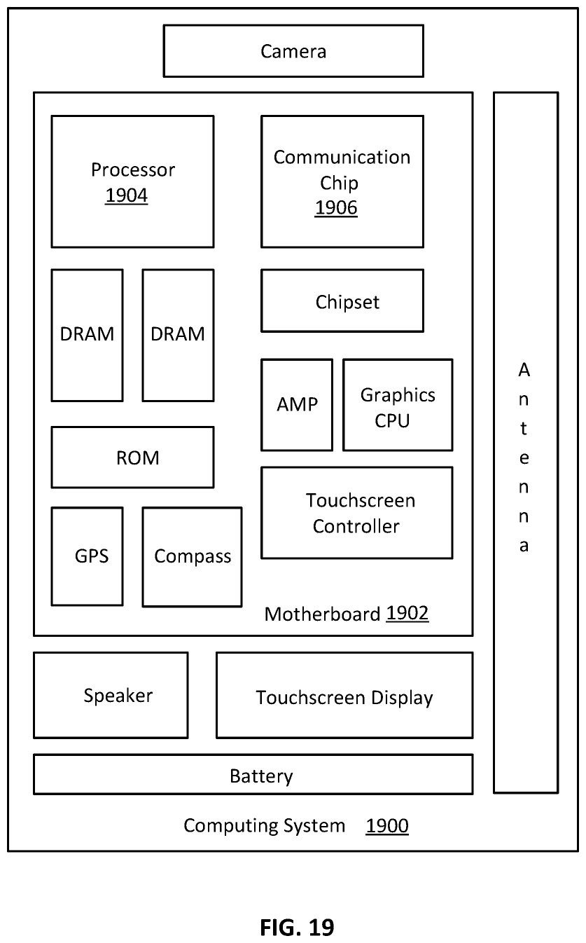

FIG. 19 is an example computing system implemented with one or more of the integrated circuit structures as disclosed herein, in accordance with some embodiments of the present disclosure. As can be seen, the computing system 1900 houses a motherboard 1902. The motherboard 1902 may include a number of components, including, but not limited to, a processor 1904 and at least one communication chip 1906, each of which can be physically and electrically coupled to the motherboard 1902, or otherwise integrated therein. As will be appreciated, the motherboard 1902 may be, for example, any printed circuit board (PCB), whether a main board, a daughterboard mounted on a main board, or the only board of system 1900, etc.

Depending on its applications, computing system 1900 may include one or more other components that may or may not be physically and electrically coupled to the motherboard 1902. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 1900 may include one or more integrated circuit structures or devices configured in accordance with an example embodiment (e.g., a module including an integrated circuit device on a substrate, the substrate having one or more semiconductor devices that include logic connections made through a backside conductive layer). In some embodiments, multiple functions can be integrated into one or more chips (e.g., for instance, note that the communication chip 1906 can be part of or otherwise integrated into the processor 1904).

The communication chip 1906 enables wireless communications for the transfer of data to and from the computing system 1900. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 1906 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 1900 may include a plurality of communication chips 1906. For instance, a first communication chip 1906 may be dedicated to shorter range wireless communications such as Wi-Fi and Bluetooth and a second communication chip 1906 may be dedicated to longer range wireless communications such as GPS, EDGE, GPRS, CDMA, WiMAX, LTE, Ev-DO, and others.

The processor 1904 of the computing system 1900 includes an integrated circuit die packaged within the processor 1904. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 1906 also may include an integrated circuit die packaged within the communication chip 1906. In accordance with some such example embodiments, the integrated circuit die of the communication chip includes one or more semiconductor devices as variously described herein. As will be appreciated in light of this disclosure, note that multi-standard wireless capability may be integrated directly into the processor 1904 (e.g., where functionality of any chips 1906 is integrated into processor 1904, rather than having separate communication chips). Further note that processor 1904 may be a chip set having such wireless capability. In short, any number of processor 1904 and/or communication chips 1906 can be used. Likewise, any one chip or chip set can have multiple functions integrated therein.

In various implementations, the computing system 1900 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 1900 may be combined or integrated in a system-on-a-chip (SoC) architecture. In some embodiments, the components may be hardware components, firmware components, software components or any suitable combination of hardware, firmware or software.

### Further Example Embodiments

The following examples pertain to further embodiments, from which numerous permutations and configurations will be apparent.

Example 1 is an integrated circuit that includes a first semiconductor device having a first semiconductor region extending in a first direction from a first source or drain region and a first gate structure extending over the first semiconductor region in a second direction different from the first direction, and a second semiconductor device having a second semiconductor region extending in the first direction from a second source or drain region and a second gate structure extending over the second semiconductor region in the second direction. The second source or drain region is spaced from the first source or drain region along the second direction. The integrated circuit also includes a conductive structure on an underside of each of the first source or drain region, the second source or drain region, and the first gate structure.

Example 2 includes the integrated circuit of Example 1, wherein the second semiconductor device comprises a third source or drain region and a frontside contact on a top surface of the third source or drain region.

Example 3 includes the integrated circuit of Example 1 or 2, further comprising a dielectric layer beneath the first and second semiconductor devices, such that the conductive structure extends through an entire thickness of the dielectric layer.

Example 4 includes the integrated circuit of Example 3, wherein the dielectric layer comprises silicon and oxygen.

Example 5 includes the integrated circuit of any one of Examples 1-4, wherein the conductive structure includes a first arm that extends in the second direction beneath both the first source or drain region and the second source or drain region, and a second arm that extends in the first direction beneath both the first source or drain region and the first gate structure, the first direction being substantially orthogonal to the second direction.

Example 6 includes the integrated circuit of any one of Examples 1-5, wherein the conductive structure is L-shaped.

Example 7 includes the integrated circuit of any one of Examples 1-6, wherein the conductive structure is one of a power rail, a ground rail, or a control signal conductor.

Example 8 includes the integrated circuit of any one of Examples 1-7, wherein the first source or drain region is a p-type source or drain region and the second source or drain region is an n-type source or drain region.

Example 9 includes the integrated circuit of any one of Examples 1-8, wherein the conductive structure comprises a conductive liner and a conductive fill.

Example 10 includes the integrated circuit of Example 9, wherein the conductive liner comprises titanium and nitrogen and the conductive fill comprises tungsten.

Example 11 includes the integrated circuit of any one of Examples 1-10, wherein the first semiconductor device and the second semiconductor device are arranged within a static random access memory (SRAM) unit cell.

Example 12 includes the integrated circuit of any one of Examples 1-10, wherein the first semiconductor device and the second semiconductor device are arranged within a memory unit cell.

Example 13 includes the integrated circuit of any one of Examples 1-10, wherein the first semiconductor device and the second semiconductor device are arranged within a logic unit cell.

Example 14 includes the integrated circuit of any one of Examples 1-10, wherein the first semiconductor device and the second semiconductor device are arranged within a multi-transistor unit cell.

Example 15 is a printed circuit board comprising the integrated circuit of any one of Examples 1-14.

Example 16 is an electronic device that includes a chip package having one or more dies. At least one of the one or more dies includes a first semiconductor device having a first semiconductor region extending in a first direction from a first source or drain region and a first gate structure extending over the first semiconductor region in a second direction different from the first direction, a second semiconductor device having a second semiconductor region extending in the first direction from a second source or drain region and a second gate structure extending over the second semiconductor region in the second direction, and a conductive structure on an underside of each of the first source or drain region, the second source or drain region, and the first gate structure. The second source or drain region is spaced from the first source or drain region along the second direction.

Example 17 includes the electronic device of Example 16, wherein the second semiconductor device comprises a third source or drain region and a frontside contact on a top surface of the third source or drain region.

Example 18 includes the electronic device of Example 16 or 17, wherein the at least one of the one or more dies further comprises a dielectric layer beneath the first and second semiconductor devices, such that the conductive structure extends through an entire thickness of the dielectric layer.

Example 19 includes the electronic device of Example 18, wherein the dielectric layer comprises silicon and oxygen.

Example 20 includes the electronic device of any one of Examples 16-19, wherein the conductive structure comprises a first arm that extends in the second direction beneath both the first source or drain region and the second source or drain region, and a second arm that extends in the first direction beneath both the first source or drain region and the first gate structure, the first direction being substantially orthogonal to the second direction.

Example 21 includes the electronic device of any one of Examples 16-20, wherein the first source or drain region is a p-type source or drain region and the second source or drain region is an n-type source or drain region.

Example 22 includes the electronic device of any one of Examples 16-21, wherein the conductive structure comprises a conductive liner and a conductive fill.

Example 23 includes the electronic device of Example 22, wherein the conductive liner comprises titanium and nitrogen and the conductive fill comprises tungsten.

Example 24 includes the electronic device of any one of Examples 16-23, wherein the first semiconductor device and the second semiconductor device are arranged within an SRAM unit cell.

Example 25 includes the electronic device of any one of Examples 16-24, further comprising a printed circuit board, wherein the chip package is coupled to the printed circuit board.

Example 26 is a method of forming an integrated circuit. The method includes forming a first fin comprising a first semiconductor region and a second fin comprising a second semiconductor region extending above a substrate, forming a first dielectric layer adjacent to a subfin portion of each of the first and second fins, forming sacrificial gates and spacer structures over the first fin and the second fin, removing portions of the first fin and the second fin not covered by the sacrificial gates and spacer structures, forming a first source or drain region at an exposed end of the first semiconductor region and a second source or drain region at an exposed end of the second semiconductor region, replacing the sacrificial gates with a first gate structure over the first semiconductor region and a second gate structure over the second semiconductor region, removing the substate to expose a backside of the first dielectric layer, replacing the subfin portion of each of the first and second fins with a second dielectric layer, forming a recess through both the first dielectric layer and the second dielectric layer such that a bottom surface of the first source or drain region, a bottom surface of the second source or drain region, and a bottom surface of the first gate structure are exposed, and forming a conductive structure within the recess.

Example 27 includes the method of example 26, wherein forming the recess comprises using a reactive ion etching (RIE) process to remove portions of the first dielectric layer and the second dielectric layer.

Example 28 includes the method of example 26 or 27, further including forming a third source or drain region at exposed ends of the second semiconductor region, and forming a conductive contact on a top surface of the third source or drain region.

Example 29 is an integrated circuit that includes a first semiconductor device having a first semiconductor region extending in a first direction from a first source or drain region and a first gate structure extending over the first semiconductor region in a second direction different from the first direction, a second semiconductor device having a second semiconductor region extending in the first direction from the first source or drain region and a second gate structure extending over the second semiconductor region in the second direction, a third semiconductor device having a third semiconductor region extending in the first direction from a second source or drain region and a third gate structure extending over the third semiconductor region in the second direction, a fourth semiconductor device having a fourth semiconductor region extending in the first direction from a third source or drain region and a fourth gate structure extending over the fourth semiconductor region in the second direction, a fifth semiconductor device having a fifth semiconductor region extending in the first direction from a fourth source or drain region and a fifth gate structure extending over the fifth semiconductor region in the second direction, and a sixth semiconductor device having a sixth semiconductor region extending in the first direction from the fourth source or drain region and a sixth gate structure extending over the sixth semiconductor region in the second direction. The first gate structure and the third gate structure are coupled together in a first gate trench, and the fourth gate structure and the sixth gate structure coupled together in a second gate trench parallel to the first gate trench. The integrated circuit further includes a conductive structure on an underside of each of the first source or drain region, the second source or drain region, and a conductive portion of the second gate trench.

Example 30 includes the integrated circuit of Example 29, wherein the first semiconductor device comprises a fifth source or drain region and a backside contact on a bottom surface of the fifth source or drain region.

Example 31 includes the integrated circuit of Example 29 or 30, further comprising a dielectric layer beneath each of the semiconductor devices, such that the conductive structure extends through an entire thickness of the dielectric layer.

Example 32 includes the integrated circuit of Example 31, wherein the dielectric layer comprises silicon and oxygen.

Example 33 includes the integrated circuit of any one of Examples 29-32, wherein the conductive structure comprises a first arm that extends in the second direction beneath both the first source or drain region and the second source or drain region, and a second arm that extends in the first direction beneath both the second source or drain region and the conductive portion of the second gate trench, the first direction being substantially orthogonal to the second direction.

Example 34 includes the integrated circuit of any one of Examples 29-33, wherein the first source or drain region is an n-type source or drain region and the second source or drain region is a p-type source or drain region.

Example 35 includes the integrated circuit of any one of Examples 29-34, wherein the conductive structure comprises a conductive liner and a conductive fill.

Example 36 includes the integrated circuit of Example 35, wherein the conductive liner comprises titanium and nitrogen and the conductive fill comprises tungsten.

Example 37 includes the integrated circuit of any one of Examples 29-36, wherein each of the first, second, third, fourth, fifth, and sixth semiconductor devices are arranged within an SRAM unit cell.

Example 38 includes the integrated circuit of any one of Examples 29-37, wherein the conductive structure is a first conductive structure and the integrated circuit further comprises a second conductive structure on an underside of each of the third source or drain region, the fourth source or drain region, and a conductive portion of the first gate trench.

Example 39 includes the integrated circuit of any one of Examples 29-37, further comprising a first gate cut extending along the first direction between the second gate structure and the fourth gate structure, and a second gate cut extending along the first direction between the third gate structure and the fifth gate structure.

Example 40 is a printed circuit board comprising the integrated circuit of any one of Examples 29-39.

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction from a first source or drain region and a first gate structure extending over the first semiconductor region in a second direction different from the first direction;
a second semiconductor device having a second semiconductor region extending in the first direction from a second source or drain region and a second gate structure extending over the second semiconductor region in the second direction, the second source or drain region being spaced from the first source or drain region along the second direction; and
a conductive structure on an underside of each of the first source or drain region, the second source or drain region, and the first gate structure.

2. The integrated circuit of claim 1, wherein the second semiconductor device comprises a third source or drain region and a frontside contact on a top surface of the third source or drain region.

3. The integrated circuit of claim 1, further comprising a dielectric layer beneath the first and second semiconductor devices, such that the conductive structure extends through an entire thickness of the dielectric layer.

4. The integrated circuit of claim 1, wherein the conductive structure comprises:
a first arm that extends in the second direction beneath both the first source or drain region and the second source or drain region; and
a second arm that extends in the first direction beneath both the first source or drain region and the first gate structure, the first direction being substantially orthogonal to the second direction.

5. The integrated circuit of claim 1, wherein the first source or drain region is a p-type source or drain region and the second source or drain region is an n-type source or drain region.

6. The integrated circuit of claim 1, wherein the conductive structure comprises a conductive liner and a conductive fill.

7. The integrated circuit of claim 1, wherein the first semiconductor device and the second semiconductor device are arranged within a static random access memory (SRAM) unit cell.

8. A printed circuit board comprising the integrated circuit of claim 1.

9. An electronic device, comprising:
a chip package comprising one or more dies, at least one of the one or more dies comprising
a first semiconductor device having a first semiconductor region extending in a first direction from a first source or drain region and a first gate structure extending over the first semiconductor region in a second direction different from the first direction;
a second semiconductor device having a second semiconductor region extending in the first direction from a second source or drain region and a second gate structure extending over the second semiconductor region in the second direction, the second source or drain region being spaced from the first source or drain region along the second direction; and
a conductive structure on an underside of each of the first source or drain region, the second source or drain region, and the first gate structure.

10. The electronic device of claim 9, wherein the at least one of the one or more dies further comprises a dielectric layer beneath the first and second semiconductor devices, such that the conductive structure extends through an entire thickness of the dielectric layer.

11. The electronic device of claim 9, wherein the conductive structure comprises:
a first arm that extends in the second direction beneath both the first source or drain region and the second source or drain region; and
a second arm that extends in the first direction beneath both the first source or drain region and the first gate structure, the first direction being substantially orthogonal to the second direction.

12. The electronic device of claim 9, wherein the first source or drain region is a p-type source or drain region and the second source or drain region is an n-type source or drain region.

13. The electronic device of claim 9, wherein the first semiconductor device and the second semiconductor device are arranged within an SRAM unit cell.

14. The electronic device of claim 9, further comprising a printed circuit board, wherein the chip package is coupled to the printed circuit board.

15. An integrated circuit comprising:
a first semiconductor device having a first semiconductor region extending in a first direction from a first source or drain region and a first gate structure extending over the first semiconductor region in a second direction different from the first direction;
a second semiconductor device having a second semiconductor region extending in the first direction from the first source or drain region and a second gate structure extending over the second semiconductor region in the second direction;
a third semiconductor device having a third semiconductor region extending in the first direction from a second source or drain region and a third gate structure extending over the third semiconductor region in the second direction;
a fourth semiconductor device having a fourth semiconductor region extending in the first direction from a third source or drain region and a fourth gate structure extending over the fourth semiconductor region in the second direction;
a fifth semiconductor device having a fifth semiconductor region extending in the first direction from a fourth source or drain region and a fifth gate structure extending over the fifth semiconductor region in the second direction;
a sixth semiconductor device having a sixth semiconductor region extending in the first direction from the fourth source or drain region and a sixth gate structure extending over the sixth semiconductor region in the second direction, wherein the first gate structure and the third gate structure are coupled together in a first gate trench, and the fourth gate structure and the sixth gate structure coupled together in a second gate trench parallel to the first gate trench; and
a conductive structure on an underside of each of the first source or drain region, the second source or drain region, and a conductive portion of the second gate trench.

16. The integrated circuit of claim 15, further comprising a dielectric layer beneath each of the semiconductor devices, such that the conductive structure extends through an entire thickness of the dielectric layer.

17. The integrated circuit of claim 15, wherein the conductive structure comprises:
a first arm that extends in the second direction beneath both the first source or drain region and the second source or drain region; and
a second arm that extends in the first direction beneath both the second source or drain region and the conductive portion of the second gate trench, the first direction being substantially orthogonal to the second direction.

18. The integrated circuit of claim 15, wherein the first source or drain region is an n-type source or drain region and the second source or drain region is a p-type source or drain region.

19. The integrated circuit of claim 15, wherein the conductive structure is a first conductive structure and the integrated circuit further comprises a second conductive structure on an underside of each of the third source or drain region, the fourth source or drain region, and a conductive portion of the first gate trench.

20. The integrated circuit of claim 15, further comprising:
a first gate cut extending along the first direction between the second gate structure and the fourth gate structure; and
a second gate cut extending along the first direction between the third gate structure and the fifth gate structure.
